(19) United States
(12) Patent Application Publication
(10) Pub. No.: US 2013/0001696 A1
(43) Pub. Date: Jan. 3, 2013

(54) SEMICONDUCTOR DEVICE AND METHOD FOR MANUFACTURING THE SAME

(75) Inventors: Shinichi Akiyama, Aizuwakamatsu (JP); Yoshiyuki Kotani, Aizuwakamatsu (JP); Toshihiro Wakabayashi, Aizuwakamatsu (JP); Masato Miyamoto, Aizuwakamatsu (JP)

(73) Assignee: FUJITSU SEMICONDUCTOR LIMITED, Yokohama-shi (JP)

(21) Appl. No.: 13/532,963

(22) Filed: Jun. 26, 2012

(30) Foreign Application Priority Data
Jun. 30, 2011 (JP) 2011-146081

(51) Int. Cl. H01L 27/06; H01L 21/8252

(52) U.S. Cl. 257/355; 438/237; 257/E27.016

(57) ABSTRACT

A gate electrode and an electrode for protective diode are coupled to each other. An insulating film below the electrode for protective diode makes a leak current flow between the electrode for protective diode and an electron transit layer and an electron supply layer when a voltage equal to or more than a given value is applied to the gate electrode. The given value is higher than a voltage by which a HEMT is on-operated and lower than a breakdown voltage of a gate insulating film.

### CROSS-REFERENCE TO RELATED APPLICATION

This application is based upon and claims the benefit of priority of the prior Japanese Patent Application No. 2011-146081, filed on Jun. 30, 2011, the entire contents of which are incorporated herein by reference.

### FIELD

The embodiments discussed herein are directed to a semiconductor device and a method for manufacturing the same.

### BACKGROUND

In a GaN-based MIS (metal-insulator-semiconductor) transistor also, similarly to in a Si-based MIS transistor, if an overvoltage exceeding a breakdown voltage of a gate insulating film is applied to the gate insulating film, the gate insulating film is destroyed. In the Si-based MIS transistor, a protective diode can be easily formed on the same substrate as a protective element.

However, it is difficult to apply a protective diode similar to that of the Si-based MIS transistor to the GaN-based MIS transistor. Thus, there is no choice but forming a protective diode on a substrate different from that of the GaN-based MIS transistor and coupling the substrates in parallel. Therefore, simplification of a structure is difficult.
Patent Literature 1: Japanese Laid-open Patent Publication No. 10-144904
Patent Literature 2: Japanese Laid-open Patent Publication No. 2002-9253

### SUMMARY

According to an aspect of the embodiment, a semiconductor device includes: a substrate; a transistor having a first nitride semiconductor layer above the substrate, a gate insulating film on the first nitride semiconductor layer, and a gate electrode on the gate insulating film; and a protective diode having a second nitride semiconductor layer above the substrate, the second nitride semiconductor layer being isolated from the first nitride semiconductor layer, an insulating film on the second nitride semiconductor layer, and an electrode on the insulating film. The gate electrode and the electrode are coupled to each other. The insulating film makes a leak current flow between the electrode and the second nitride semiconductor layer when a voltage equal to or more than a given value is applied to the gate electrode. The given value is higher than a voltage by which the transistor is on-operated and is lower than a breakdown voltage of the gate insulating film.

According to another aspect of the embodiment, in a method for manufacturing a semiconductor device, a first nitride semiconductor layer and a second nitride semiconductor layer isolated from each other above a substrate are formed. A transistor having a gate insulating film on the first nitride semiconductor layer and a gate electrode on the gate insulating film is formed. A protective diode having an insulating film on the second nitride semiconductor layer and an electrode on the insulating film is formed. The gate electrode and the electrode are coupled to each other. The insulating film makes a leak current flow between the electrode and the second nitride semiconductor layer when a voltage equal to or more than a given value is applied to the gate electrode. The given value is higher than a voltage by which the transistor is on-operated and lower than a breakdown voltage of the gate insulating film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram depicting a structure of a semiconductor device according to a first embodiment;

FIG. 2 is a graph depicting a leak characteristic of one example of a GaN-based MIS diode;

FIG. 3 is a graph depicting a forward direction leak characteristic of one example of a Si-based MIS capacitor;

FIG. 4A and FIG. 4B are diagrams each depicting a band scheme of a multilayer body of a semiconductor, a silicon nitride, and a metal electrode;

FIG. 5 is a graph depicting a relation between a thickness of a silicone nitride film and a gate voltage Vg by which a leak current reaches 10 mA;

FIG. 6 is a graph depicting a leak characteristic of another example of a GaN-based MIS diode;

FIG. 7 is a graph depicting a relation between a thickness of an aluminum nitride film and a gate voltage Vg by which a leak current reaches 10 mA;

FIG. 8 is a graph depicting a leak characteristic in an MOS transistor whose insulating film includes an aluminum oxide film;

FIG. 9 is a graph depicting a leak characteristic after a breakdown in an aluminum oxide film;

FIG. 10A to FIG. 10S are cross-sectional views depicting a method for manufacturing a semiconductor device according to a second embodiment in order of process steps;

FIG. 11A to FIG. 11L are cross-sectional views depicting a method for manufacturing a semiconductor device according to a third embodiment in order of process steps;

FIG. 12A to FIG. 12L are cross-sectional views depicting a method for manufacturing a semiconductor device according to a fourth embodiment in order of process steps;

FIG. 13A to FIG. 13M are cross-sectional views depicting a method for manufacturing a semiconductor device according to a fifth embodiment in order of process steps;

FIG. 14A to FIG. 14O are cross-sectional views depicting a method for manufacturing a semiconductor device according to a sixth embodiment in order of process steps;

FIG. 15 is a cross-sectional view depicting a modified example of the sixth embodiment;

FIG. 16A to FIG. 16N are cross-sectional views depicting a method for manufacturing a semiconductor device according to a seventh embodiment in order of process steps;

FIG. 17A to FIG. 17L are cross-sectional views depicting a method for manufacturing a semiconductor device according to an eighth embodiment in order of process steps;

FIG. 18A to FIG. 18L are cross-sectional views depicting a method for manufacturing a semiconductor device according to a ninth embodiment in order of process steps; and

FIG. 19A to FIG. 19L are cross-sectional views depicting a method for manufacturing a semiconductor device according to a tenth embodiment in order of process steps.

### DESCRIPTION OF EMBODIMENT

### First Embodiment

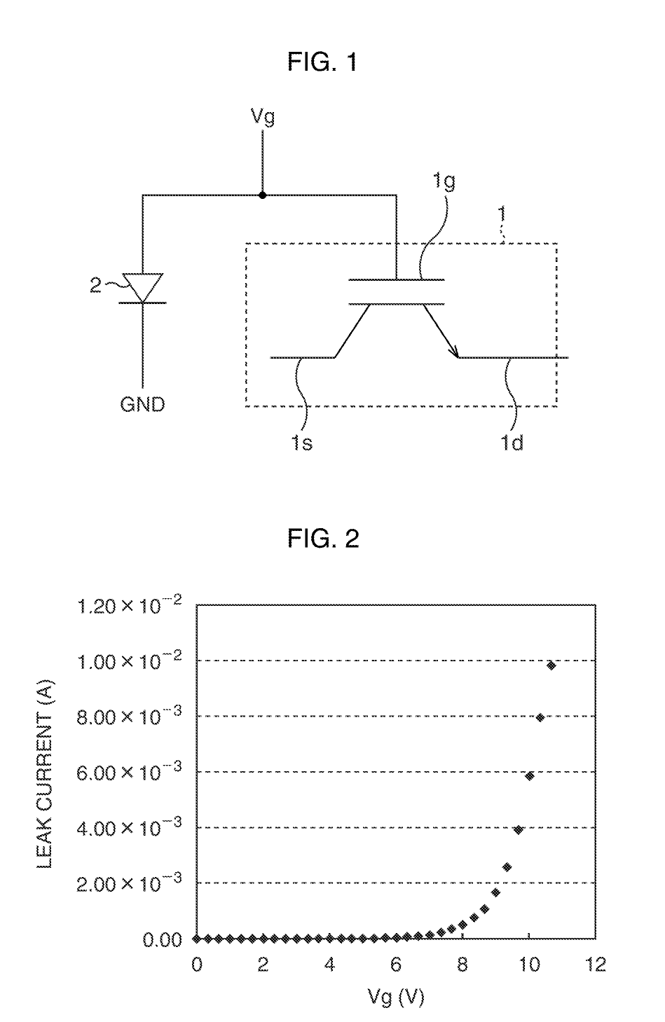

First, a first embodiment will be described. FIG. 1 is a diagram depicting a structure of a semiconductor device according to the first embodiment.

As illustrated in FIG. 1, in the first embodiment, a high electron mobility transistor (HEMT) 1 having a gate 1g, a source 1s, and a drain 1d is provided as a GaN-based MIS transistor.

Further, a protective diode 2 whose anode is coupled to the gate 1g is also provided. A cathode of the protective diode 2 is grounded, and a gate voltage Vg is applied to the gate 1g and the anode of the protective diode 2. The protective diode 2 is formed on a substrate the same as that of the HEMT 1. As an electron transit layer and an electron supply layer of the HEMT 1 and the cathode of the protective diode 2, nitride semiconductor layers are used, the nitride semiconductor layers being isolated between a HEMT 1 part and a protective diode 2 part thereof. The HEMT 1 part of the nitride semiconductor layers is one example of a first nitride semiconductor layer, while the protective diode layer 2 part is one example of a second nitride semiconductor layer.

Here, the protective diode 2 will be described. The protective diode 2 includes a semiconductor film (second nitride semiconductor layer), an insulating film, and a metal electrode, and is a MIS diode. As the insulating film, there is used an insulating film which makes a leak current flow between the metal electrode of the anode and the semiconductor film when a voltage equal to or more than a given value is applied to the gate 1g. Here, the given value is a value higher than a voltage by which the HEMT 1 is on-operated and lower than a breakdown voltage of a gate insulating film of the HEMT 1. A material of the insulating film of the protective diode 2 is, for example, different from a material of the gate insulating film of the HEMT 1, and in a case that the gate insulating film of the HEMT 1 is an aluminum oxide film, the insulating film of the protective diode 2 is a silicon nitride film, an aluminum nitride film, or the like. In other words, for example, a dielectric constant of the insulating film of the protective diode 2 is smaller than a dielectric constant of the gate insulating film.

FIG. 2 is a graph depicting a leak characteristic of one example of a GaN-based MIS diode. This example is made under an assumption of a GaN-based HEMT, and a GaN film (electron transit layer) and an AlGaN film (electron supply layer) thereon are used as a semiconductor film. Further, as an insulating film, a silicon nitride film with a thickness of 20 nm is used, and an area of a metal film is 19700 μm². As illustrated in FIG. 2, a leak current starts to increase by a gate voltage Vg of about 6V, and the leak current reaches 10 mA by a gate voltage Vg of a little more than 10V. In protection of a general GaN-based HEMT, it is preferable that a leak current of 10 mA flows to a protective element by a gate voltage of about 5V to 40 V.

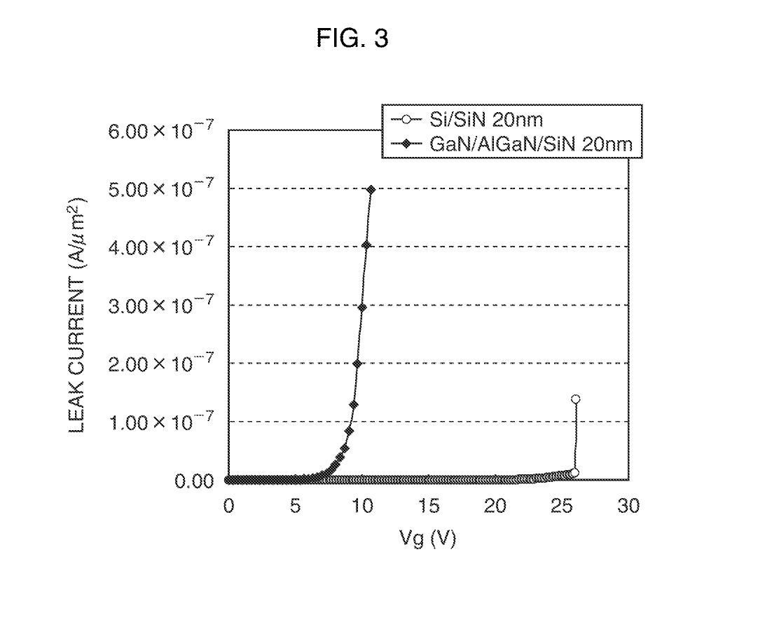

A forward direction leak characteristic of one example of a Si-based MIS capacitor is depicted in FIG. 3 for the sake of comparison. This example is made under an assumption of a Si-based MIS transistor, and a Si film is used as a semiconductor film. Further, a thickness of a silicon nitride film is 20 nm similarly to the example depicted in FIG. 2. As illustrated in FIG. 3, in the Si-based MIS capacitor, a leak current scarcely flows and a breakdown occurs by about 26 V.

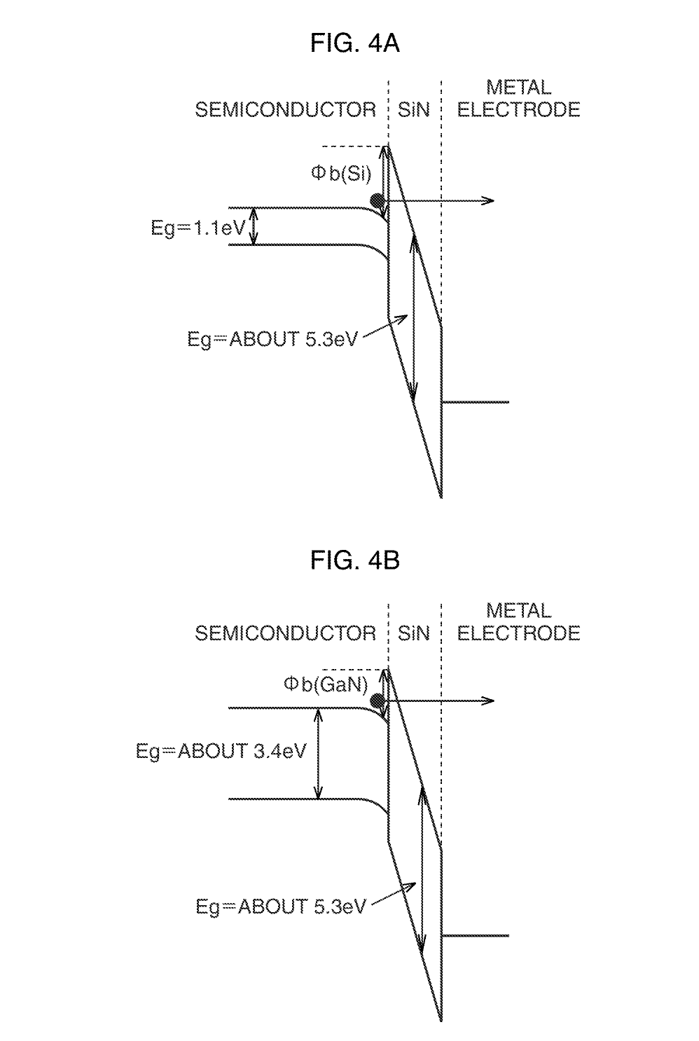

As indicated above, a large difference exists in leak characteristics between a GaN-based MIS diode and a Si-based MIS capacitor, even though both are silicon nitride films. This is caused by a difference in band gaps of a semiconductor and an insulator, and so on. FIG. 4A and FIG. 4B are diagrams each depicting a band scheme of a multilayer body of a semiconductor, a silicon nitride, and a metal electrode. FIG. 4A depicts the band scheme in a case that a Si substrate is used as a semiconductor, while FIG. 4B depicts the band scheme in a case that a GaN substrate is used as a semiconductor. As illustrated in FIG. 4A and FIG. 4B, the band gap of GaN is closer to the band gap of the silicon nitride than the band gap of Si, and a barrier height Φb (Si) of Si is larger than a barrier height Φb (GaN) of GaN. Such a tendency is similar in a case that AlGaN is used instead of GaN.

According to a Fowler-Nordheim model, which is general as a scheme of a tunnel current to an insulating film, a tunnel current J_{FN} is given by a following formula (numeral 1).

$$l ɛ x = \frac{{q}^{2} {e}_{ox}^{2} m}{{Bnhm}^{′} {Φ}_{b}} \cdot exp ( - \frac{ɛ \sqrt{2 {m}^{′}} {( q {Φ}_{b} )}^{\text{?}}}{3 q ℏ} ) \\ ( q \text{:} electric charge {e}_{ox} \text{:} electric field applied to insulating film \\ {m}^{′} \text{:} effective mass m \text{:} mass of electron \\ h \text{:} Planck ' s constant ℏ \text{:} reduced Planck ' s constant ) \\ \text{?} \text{indicates text missing or illegible when filed} \qquad [ Numeral 1 ]$$

As is obvious from the above formula (numeral 1), the smaller the barrier height Φb is, the larger the tunnel current J_{FN} is. Accordingly, the leak characteristics differ largely depending on combination of a material of a semiconductor film and a material of an insulating film, and as the barrier height Φb is large, the breakdown is more apt to occur. In other words, mechanisms of the tunnel current and the breakdown are different largely from each other between the Si-based semiconductor and the GaN-based semiconductor, and thus it cannot be said that mere application of a technique related to the Si-based semiconductor to the GaN-based semiconductor can bring about similar operation and effect.

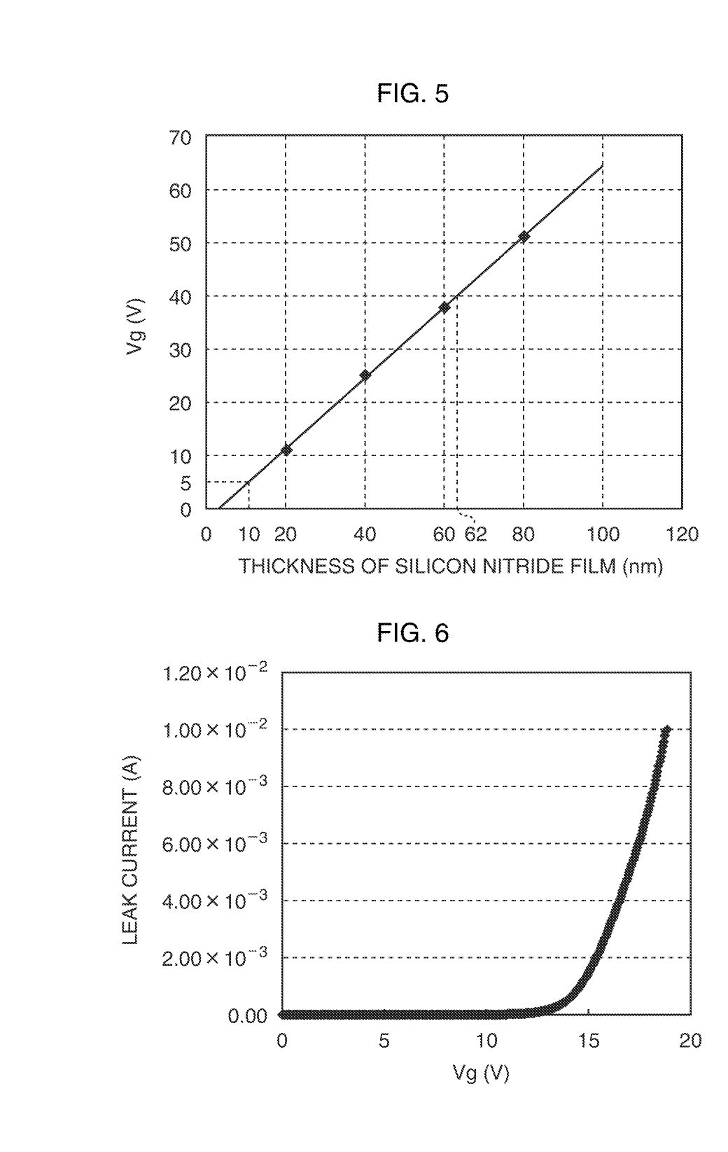

FIG. 5 is a graph depicting a relation between a thickness of a silicon nitride film in a GaN-based MIS diode and a gate voltage Vg by which a leak current reaches 10 mA. From FIG. 5 it is obvious that a gate voltage Vg by which a leak current of a given value (for example, 10 mA) flows can be arbitrarily controlled with the thickness of the silicon nitride film. Further, as a protective element of a general GaN-based MIS transistor (for example, HEMT), a protective diode with which a leak current of 10 mA flows by about 5 V to 40 V is preferable. Therefore, when the relation depicted in FIG. 5 is taken into consideration, as an insulating film of the protective diode 2, a silicon nitride film with a thickness of 10 nm to 62 nm is preferable.

Further, it is also possible to use an aluminum nitride film as an insulating film of the protective diode 2. FIG. 6 is a graph depicting a leak characteristic of another example of a GaN-based MIS diode. This example is made under assumption of a GaN-based HEMT, and a GaN film (electron transit layer) and an AlGaN film (electron supply layer) thereon are used as a semiconductor film. Further, an aluminum nitride film with a thickness of 40 nm is used as an insulating film, and an area of a metal film is 19700 μm². As illustrated in FIG. 6, a leak current starts to increase by a gate voltage Vg of about 12 V and the leak current reaches 10 mA by a gate voltage Vg of about 18 V.

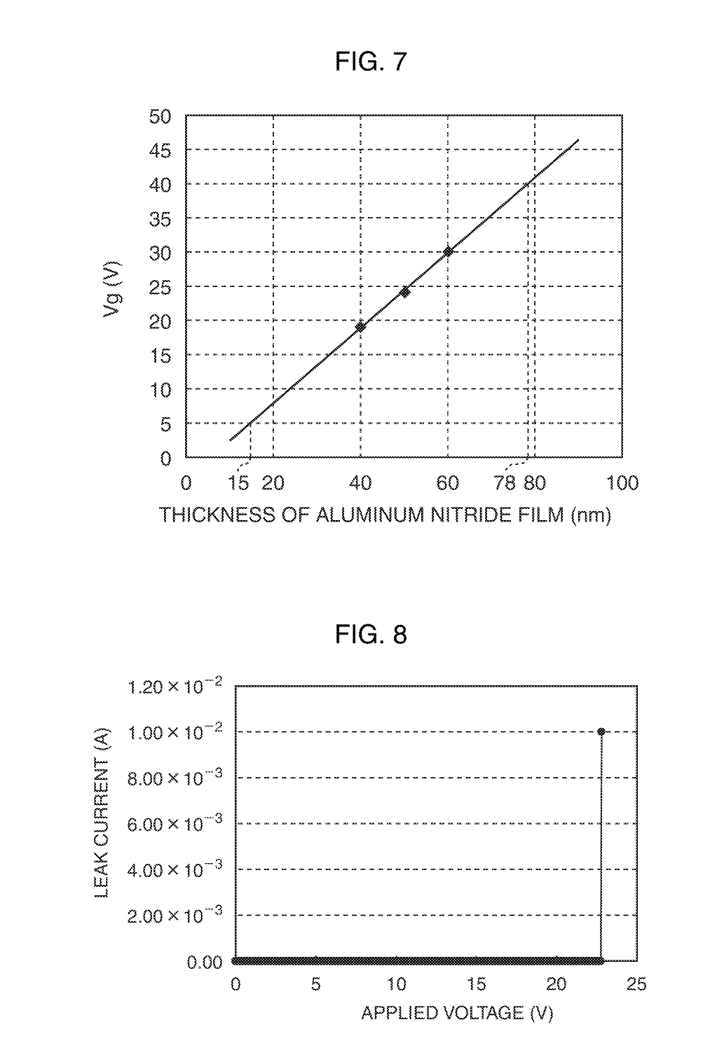

FIG. 7 is a graph depicting a relation between a thickness of an aluminum nitride film in a GaN-based MIS diode and a gate voltage Vg by which a leak current reaches 10 mA. From FIG. 7 it is obvious that a gate voltage Vg by which a leak current of a given value (for example, 10 mA) flows can be arbitrarily controlled with the thickness of the aluminum nitride film. Further, as described above, as a protective element of a general GaN-based MIS transistor (for example, HEMT), a protective diode with which a leak current of 10 mA flows by about 5 V to 40 V is preferable. Therefore, when the relation depicted in FIG. 7 is taken into consideration, as an insulating film of the protective diode 2, an aluminum nitride film with a thickness of 15 nm to 78 nm is also preferable.

As described above, a silicon nitride film and an aluminum nitride film between a GaN-based semiconductor and a metal make a leak current flow upon application of a certain voltage. This is because band gaps of a silicon nitride and an aluminum nitride are each about 5.3 eV and about 6.1 eV, and are close to a band gap (about 3.4 eV) of GaN and a band gap (about 3.4 eV to 4 eV) of AlGaN. Besides, as an insulating film of the protective diode, a material with a band gap of about 4.0 eV to 6.1 eV and with a thickness of 10 nm to 80 nm is preferable. As such a material, there can be cited, other than a silicon nitride and an aluminum nitride, a gadolinium oxide, a hafnium oxide, a hafnium aluminate, and a gallium oxide. Band gaps of the gadolinium oxide, the hafnium oxide, and the hafnium aluminate, and the gallium oxide are each about 5.4 eV, about 5.7 eV, about 5.7 eV to 8.8 eV, and about 4.8 eV.

Further, as the insulating film, there may be used, for example, an insulating film whose potential barrier width against a nitride semiconductor layer and a metal electrode of a protective diode is smaller than a potential barrier width of a gate insulating film against a nitride semiconductor layer and a gate electrode of a transistor. Further, for example, a barrier height of a metal electrode against a nitride semiconductor layer of a protective diode is lower than a barrier height of a gate electrode against a nitride semiconductor layer of a transistor.

Note that a band gap of an aluminum oxide mainly used as a gate insulating film of a GaN-based HEMT is about 8.8 eV. FIG. 8 is a graph depicting a leak characteristic in an MOS (metal-oxide-semiconductor) capacitor whose insulating film includes an aluminum oxide film. In this example, a GaN film is used as a semiconductor film, an aluminum oxide film with a thickness of 20 nm is formed thereon, a silicon nitride film with a thickness of 20 nm is formed thereon, and a metal film is formed thereon. An area of the metal film is 19700 μm². As illustrated in FIG. 8, in this capacitor, a leak current scarcely flows and a breakdown occurs in the aluminum oxide film by an applied voltage of about 23 V. Such a tendency is similar to a tendency of the Si-based MIS capacitor illustrated in FIG. 3.

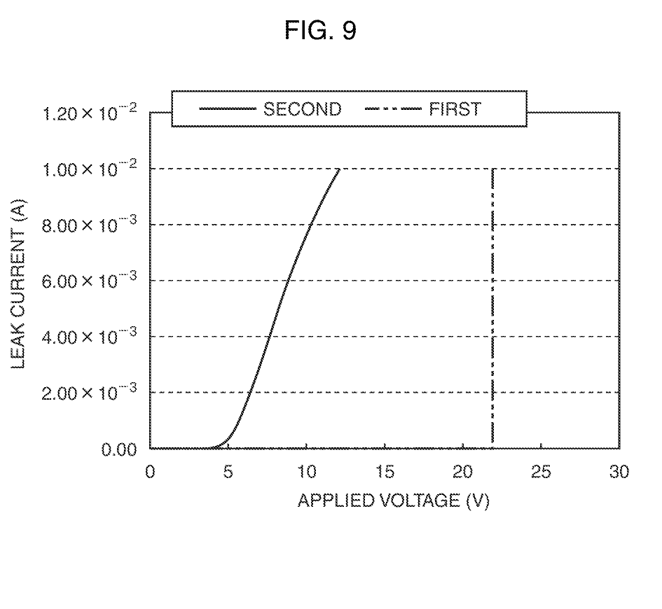

In the capacitor whose leak characteristic is illustrated in FIG. 8, if the leak characteristic is measured again after the occurrence of breakdown in the aluminum oxide film, a characteristic capable of functioning as a protective diode emerges. FIG. 9 is a graph depicting a leak characteristic after the occurrence of breakdown in the aluminum oxide film. As illustrated in FIG. 9, in the second measurement, that is, a measurement after breakdown is made to occur in the aluminum oxide film in the first measurement, a leak current starts to increase by an applied voltage of about equal to or more than 5 V and the leak current reaches 10 mA by an applied voltage of about 12 V. This is because in spite of the occurrence of breakdown in the aluminum oxide film the silicon nitride film functions as the insulating film of the protective diode. Therefore, even if the aluminum oxide film is included in the insulating film of the protective diode, as long as an insulating film suitable for an insulating film of the protective diode, such as a silicon nitride film, an aluminum nitride film, or the like is included other than the aluminum oxide film, it is possible to obtain a MIS diode, for example, by causing a breakdown in the aluminum oxide film by intentional application of an overvoltage. This is similar in a case that a silicon oxide film with a band gap of equal to or more than about 8 eV is used instead of the aluminum oxide film.

### Second Embodiment

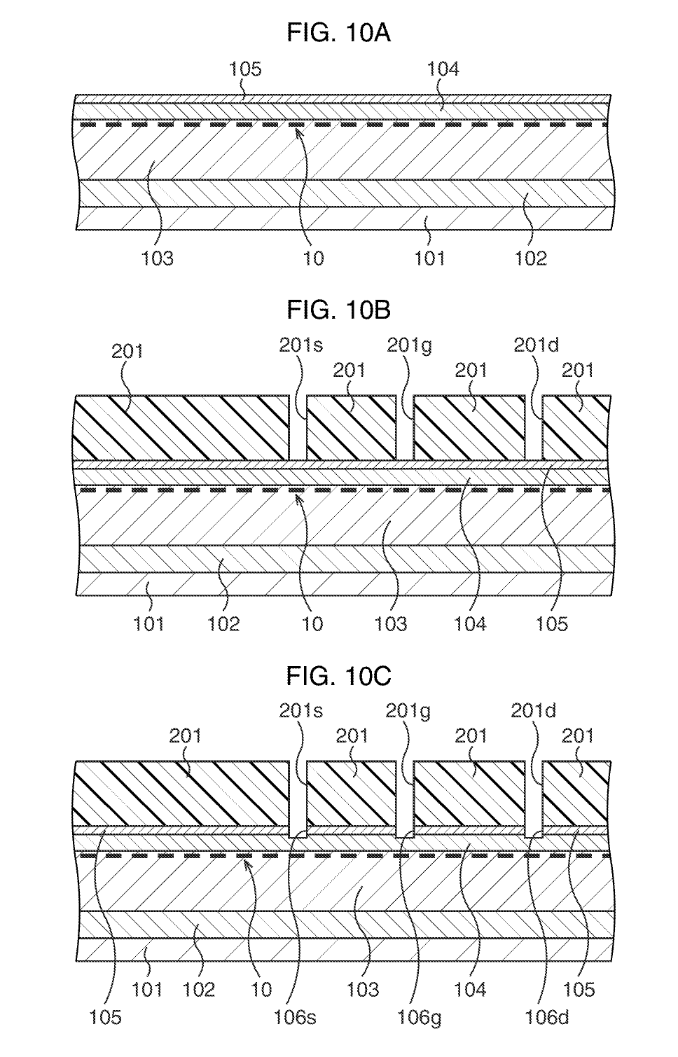

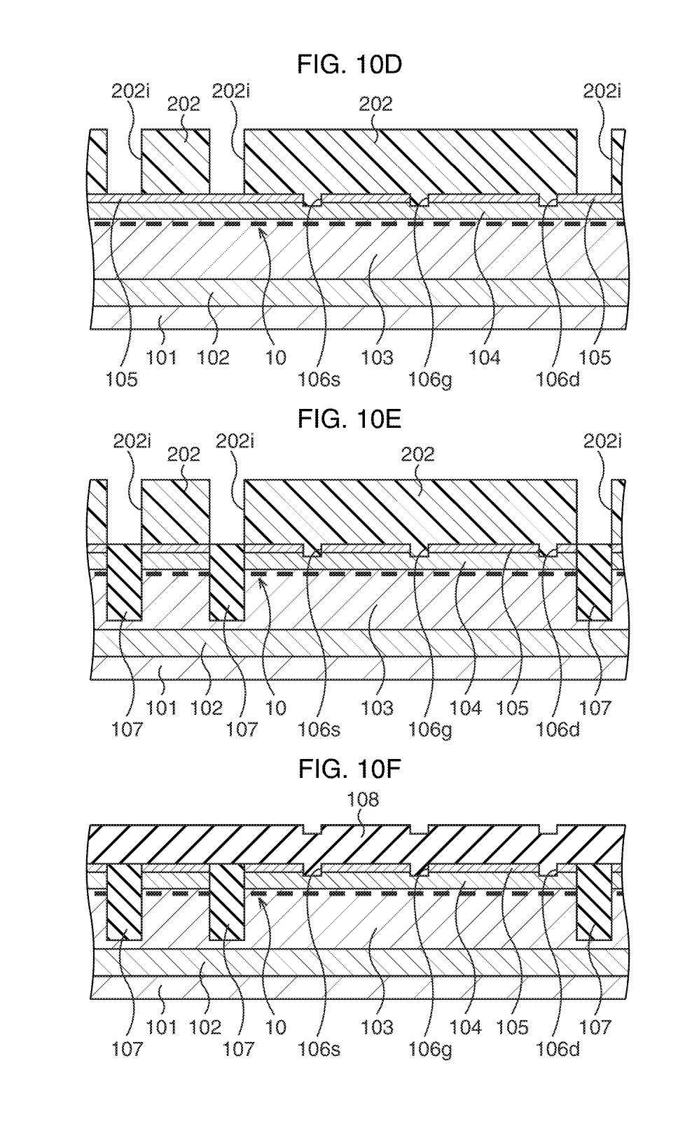

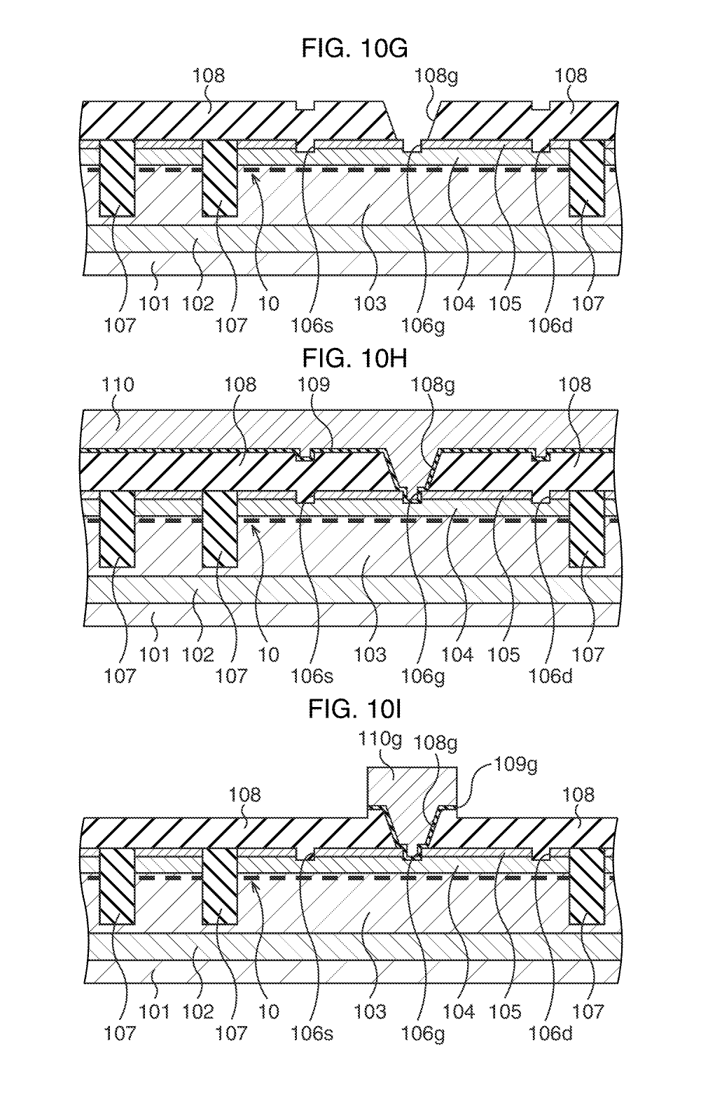

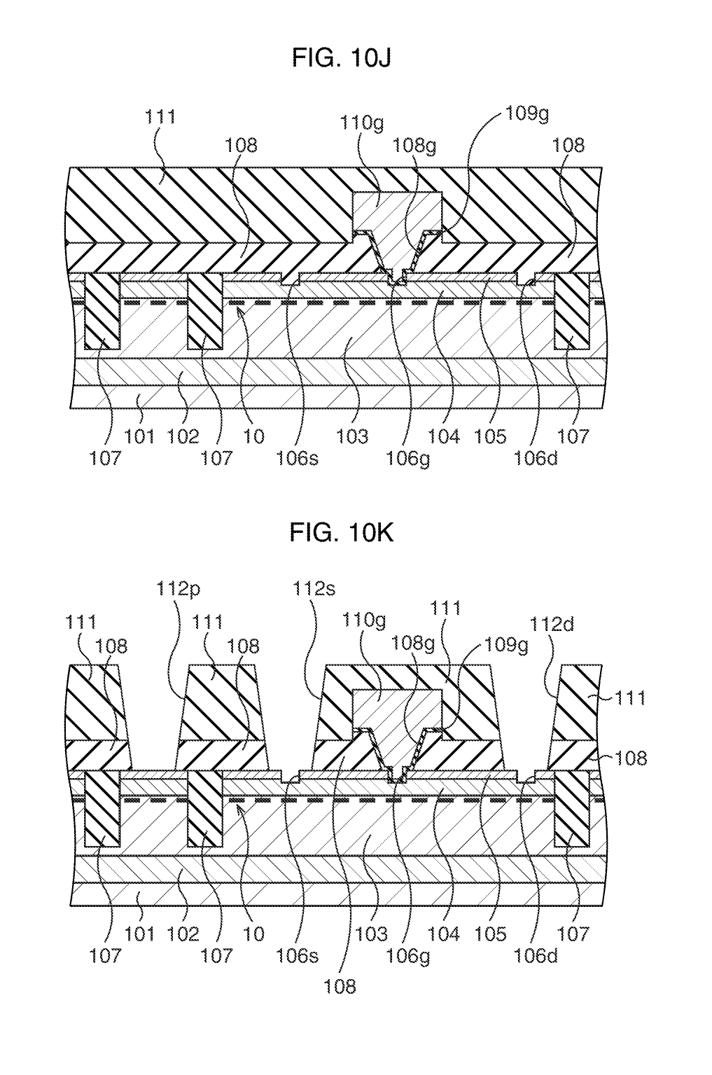

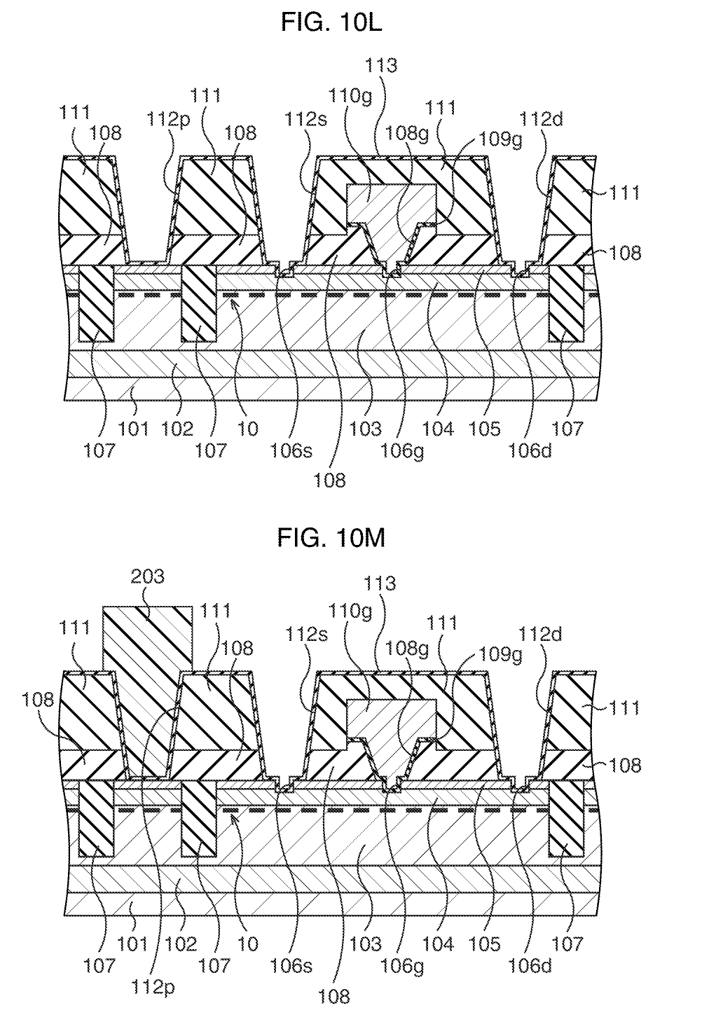

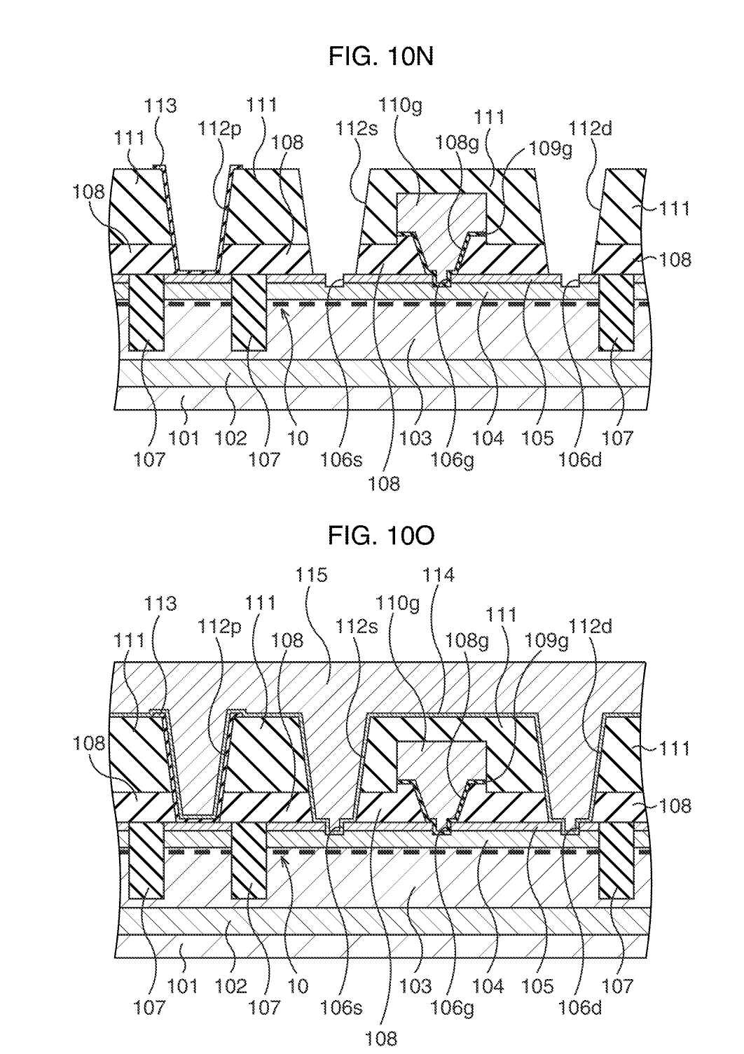

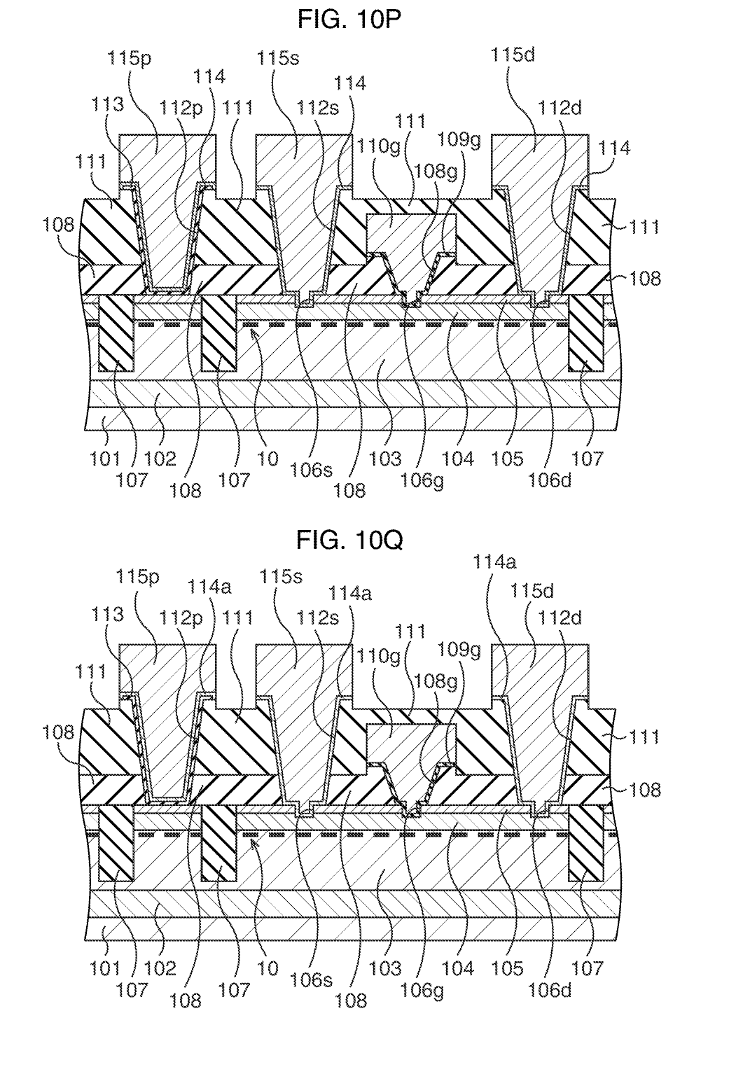

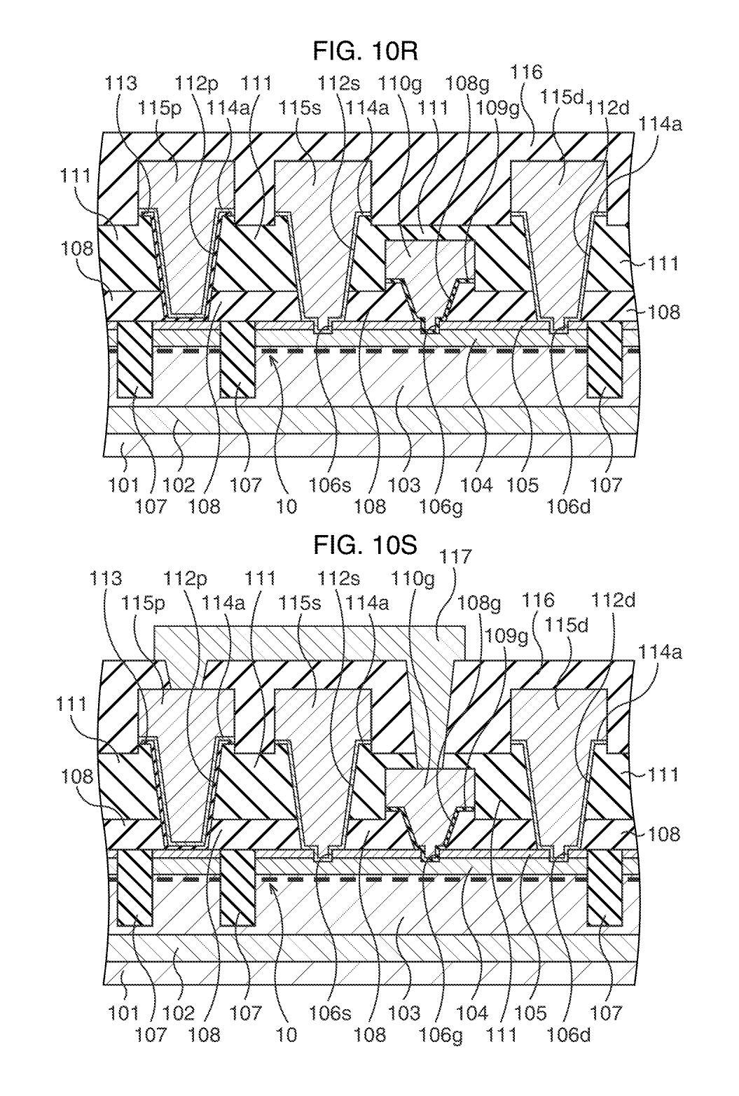

Next, a second embodiment will be described. Here, for the sake of convenience, a cross-sectional structure of a semiconductor device is described together with a method for manufacturing the same. FIG. 10A to FIG. 10S are cross-sectional views depicting a method for manufacturing a semiconductor device according to the second embodiment in order of process steps. In the second embodiment, an electrode of a MIS diode is formed after formation of a gate electrode of a HEMT, concurrently with a source electrode and a drain electrode of the HEMT.

First, as illustrated in FIG. 10A, a buffer layer 102 is formed on a substrate 101 of a Si substrate or the like. As the buffer layer 102, for example, an AlN layer with a thickness of about 2 μm is formed. A multilayer body made by stacking a plurality of AlN layers and GaN layers alternately may be formed as the buffer layer 102, and an AlGaN layer in which Al compositions decreases as departing from the interface with the substrate 101 may be formed (AlN in an interface with the substrate 101). Thereafter, an electron transit layer 103 is formed on the buffer layer 102. As the electron transit layer 103, for example, a GaN layer with a thickness of about 1 μm to 3 μm is formed. Subsequently, an electron supply layer 104 is formed on the electron transit layer 103. As the electron supply layer 104, for example, an AlGaN layer with a thickness of about 5 nm to 40 nm is formed. Since a band gap of AlGaN of the electron supply layer 104 is larger than a band gap of GaN of the electron transit layer 103, a quantum well occurs, and electrons are stored in the quantum well. As a result, a two-dimensional electron gas (2DEG) 10 being a carrier occurs in a neighborhood of an interface with the electron supply layer 104, of the electron transit layer 103. Next, a cap layer 105 is formed oh the electron supply layer 104. As the cap layer 105, for example, a GaN layer with a thickness of about 0.1 nm to 5 nm is formed.

As illustrated in FIG. 10B, a resist pattern 201 having openings 201g, 201s, and 201d, respectively, in respective regions in which recesses of a gate, a source, and a drain of the HEMT are to be formed is formed on the cap layer 105.

As illustrated in FIG. 10C, using the resist pattern 201 as a mask, the cap layer 105 is etched, thereby to form a recess 106g for the gate, a recess 106s for the source, and a recess 106d for the drain. In this etching, dry etching is performed, for example, with a parallel flat type etching device, in a chlorine gas atmosphere, with a substrate temperature being 25° C. to 150° C., a pressure being 10 mT to 2 Torr, and an RF power being 50 W to 400 W. Alternatively, dry etching may be performed with an electron cyclotron resonance (ECR) etching device or an inductively coupled plasma (ICP) etching device, with a pressure being 1 mT to 50 mTorr, and a bias power being 5 W to 80 W. Note that formation of the recess 106g and formation of the recesses 106s and 106d may be different process steps. Further, formation of recesses 106s and 106d may be omitted. Then, the resist pattern 201 is removed.

As illustrated in FIG. 10D, a resist pattern 202 having an opening 202i in a region in which an element isolation region is to be formed is formed on the cap layer 105.

As illustrated in FIG. 10E, ion implantation is performed using the resist pattern 202 as a mask, thereby to form an element isolation region 107. In this ion implantation, crystals of the electron supply layer 104 and the electron transit layer 103 are destroyed thereby to make the 2DEG 10 vanish, so that an insulating region is formed as the element isolation region 107. Then, the resist pattern 202 is removed.

As illustrated in FIG. 10F, a protective film 108 is formed on an entire surface. As the protective film 108, for example, a silicon nitride film with a thickness of about 20 nm to 500 nm is formed by a plasma chemical vapor deposition (CVD) method. As the protective film 108, a silicon oxide film, or a multilayer body of a silicon nitride film and a silicon oxide film may be formed. Further, the protective film 108 may be formed by a thermal CVD method or an atomic layer deposition (ALD) method.

As illustrated in FIG. 10G, an opening 108g is formed in a region in which the gate electrode is to be formed, of the protective film 108. In forming the opening 108g, for example, a resist pattern exposing the region in which the opening 108g is to be formed and covering the other part is formed on the protective film 108, and using this resist pattern as a mask, wet etching using a chemical solution containing fluorine is performed, and then this resist pattern is removed.

As illustrated in FIG. 10H, an insulating film 109 to be a gate insulating film and a conductive film 110 to be the gate electrode are formed on an entire surface. As the insulting film 109, for example, an aluminum oxide film with a thickness of 20 nm is formed by an ALD method. As the insulating film 109, a silicon nitride film, a silicon oxide film, an aluminum nitride film, a hafnium oxide film, a hafnium aluminate film, a zirconium oxide film, a hafnium silicate film, a hafnium silicate nitride film, or a gallium oxide film may be formed. Further, it is also permissible to form a multilayer body of two or more kinds of an aluminum oxide film, a silicon nitride film, a silicon oxide film, an aluminum nitride film, a hafnium oxide film, a hafnium aluminate film, a zirconium oxide film, a hafnium silicate film, a hafnium silicate nitride film, and a gallium oxide film. As the conductive film 110, for example, a multilayer body of a high work function film with a thickness of about 50 nm and with a work function of equal to or more than 4.5 and an Al film with a thickness of about 400 nm thereon is formed by a physical vapor deposition (PVD) method. As the high work function film, there may be cited films of materials with a work function of equal to or more than 4.5 eV, such as Au, Ni, Co, TiN (nitrogen rich), TaN (nitrogen rich), TaC (carbon rich), Pt, W, Ru, Ni₃Si, and Pd. Note that it is preferable to perform an annealing treatment (PDA: post deposition anneal) between formation of the insulating film 109 and formation of the conductive film 110. A temperature and time of the annealing treatment may be, for example, 550° C. and 60 seconds. By this annealing treatment, C and H contained in the insulating film 109 can be removed.

As illustrated in FIG. 10I, the conductive film 110 and the insulating film 109 are patterned thereby to form a gate electrode 110g and a gate insulating film 109g. In patterning the conductive film 110 and the insulating film 109, a resist pattern covering a region in which the gate electrode 110g is to be formed and exposing the other part is formed on the conductive film 110, dry etching is performed using this resist pattern as a mask, and the resist pattern is removed. On this occasion, an upper layer part of the protective film 108 is also etched by overetching, so that an exposed upper surface of the protective film 108 is planarized.

As illustrated in FIG. 10J, a protective film 111 is formed on an entire surface. As the protective film 111, for example, a silicon oxide film with a thickness of about 300 nm is formed. It is preferable that an upper surface of the protective film 111 is planarized. For the above, for example, a material of the protective film 111 is applied by a spin coating method, and thereafter solidification by curing is performed. It is also permissible that a protective film 111 with an uneven surface is formed and thereafter a chemical mechanical processing (CMP) is performed.

As illustrated in FIG. 10K, an opening 112s, an opening 112d, and an opening 112p are each formed in respective regions in which the source electrode, the drain electrode, and a protective diode are to be formed, of the protective film 111 and the protective film 108. In forming the opening 112s, the opening 112d, and the opening 112p, for example, a resist pattern exposing the respective regions in which the opening 112s, the opening 112d, and the opening 112p are to be formed and covering the other part is formed on the protective film 111, dry etching is performed using the resist pattern as a mask, and the resist pattern is removed. The dry etching is performed, for example, with a parallel flat type etching device being used, in a gas atmosphere containing CF₄, SF₆, CHF₃, or fluorine, a substrate temperature being 25° C. to 200° C., a pressure being 10 mT to 2 Torr, and an RF power being 10 W to 400 W.

As illustrated in FIG. 10L, an insulating film 113 of the protective diode (MIS diode) is formed on an entire surface. As the insulating film 113, for example, a silicon nitride film with a thickness of about 20 nm is formed by a CVD method. As the insulating film 113, corresponding to a breakdown voltage of the gate insulating film 109g, an aluminum nitride film, a gadolinium oxide film, a hafnium oxide film, a hafnium aluminate film, and a gallium oxide film may also be formed. Further, it is also permissible to form a multilayer body of two or more kinds of a silicon nitride film, an aluminum nitride film, a gadolinium oxide film, a hafnium oxide film, a hafnium aluminate film, and a gallium oxide film. A thickness of the insulating film 113 is, for example, 10 nm to 80 nm, and if the silicon nitride film only is used, it is preferable that its thickness is 10 nm to 62 nm, and if the aluminum nitride film only is used, it is preferable that its thickness is 15 nm to 78 nm.

As illustrated in FIG. 10M, a resist pattern 203 covering a region in which an electrode of the protective diode is to be formed and exposing the other part is formed on the insulating film 113.

As illustrated in FIG. 10N, the insulating film 113 is etched using the resist pattern 203 as a mask, and the resist pattern 203 is removed. In this etching, for example, wet etching using a chemical solution containing fluorine is performed.

As illustrated in FIG. 10O, a conductive film 114 and a conductive film 115 to be the source electrode, the drain electrode, and the electrode of the protective diode are formed on an entire surface. As the conductive film 114, for example, a low work function film such as a Ta film with a thickness of about 1 nm to 100 nm is formed by a PVD method. As the low work function film, there may be cited films of materials with a work function of less than 4.5 eV, such as Al, Ti, TiN (metal rich), Ta, TaN (metal rich), Zr, TaC (metal rich), NiSi₂, and Ag. A low work function metal is used as the conductive film 114 in order to obtain a low contact resistance by decreasing a barrier to a semiconductor directly below the source electrode and the drain electrode. As the conductive film 115, for example, a film whose main material is Al (for example, an Al film) and with a′thickness of about 20 nm to 500 nm is formed by a PVD method.

As illustrated in FIG. 10P, the conductive film 115 and the conductive film 114 are patterned thereby to form a source electrode 115s, a drain electrode 115d, and an electrode 115p for protective diode. In patterning the conductive film 115 and the conductive film 114, a resist pattern covering respective regions in which the source electrode 115s, the drain electrode 115d, and the electrode 115p for protective diode are to be formed and exposing the other part is formed on the conductive film 115, dry etching is performed using this resist pattern as a mask, and the resist pattern is removed. On this occasion, an upper layer part of the protective film 111 may be etched by overetching.

As illustrated in FIG. 10Q, an annealing treatment is performed thereby to change the conductive film 114 to a conductive film 114a with a lower contact resistance. For example, an atmosphere of this annealing treatment is an atmosphere of one kind or two or more kinds of noble gas, nitrogen, oxygen, ammonia, and hydrogen, a time is equal to or less than 180 seconds, and a temperature is 550° C. to 650° C. For example, for example, a heat treatment of 600° C. is performed for 60 seconds in a nitrogen atmosphere. By this annealing treatment, the conductive film 114 and Al in the conductive film 115 react with each other, generating a small amount of Al spikes to a semiconductor part (cap layer 105 and electron supply layer 104). As a result, a contact resistance is reduced. On this occasion, the low work function of Al also contributes to lowering of the resistance.

As illustrated in FIG. 10R, a protective film 116 is formed on an entire surface. As the protective film 116, for example, a silicon oxide film with a thickness of about 1000 nm is formed. It is preferable that an upper surface of the protective film 116 is planarized. For the above, for example, a material of the protective film 116 is applied by a spin coat method, and thereafter solidification by curing is performed. Further, it is also permissible that a protective film 116 with an uneven surface is formed and thereafter CMP is performed.

As illustrated in FIG. 10S, an opening exposing the gate electrode 110g is formed in the protective film 116 and the protective film 111, and an opening exposing the electrode 115p for protective diode is formed in the protective film 116. Then, a wiring 117 coupling the gate electrode 110g and the electrode 115p for protective diode to each other via those openings is formed. Note that it is preferable that at a time of forming the opening exposing the gate electrode 110g and the opening exposing the electrode 115p for protective diode, an opening exposing the source electrode 115s and an opening exposing the drain electrode 115d are also formed, and that at a time of forming the wiring 117, a wiring for the source and a wiring for the drain are also formed. These openings may be formed, for example, by etching with using a resist pattern as a mask. Further, the wiring 117 and the like may be formed by forming a metal film, patterning thereof, and the like.

In the second embodiment, as described above, for example, the aluminum oxide film with the thickness of 20 nm is used as the gate insulating film 109g, and the silicon nitride film with the thickness of about 20 nm is used as the insulating film 113 of the protective diode (MIS diode). A breakdown voltage of the aluminum oxide film with the thickness of 20 nm is about 23 V as illustrated in FIG. 8. Further, to the silicon nitride film with the thickness of about 20 nm, a leak current of 10 mA flows when a voltage of about 12 V is applied. Accordingly, even if a voltage exceeding a breakdown voltage of the gate insulating film 109g is applied to the gate electrode 110g as a surge voltage out of design, a leak current flows to the MIS diode before the gate insulating film 109g is broken down. For example, in a case that a gate voltage of an ordinary operation of a HEMT is designed to be 7 V, even if a surge voltage of about 30 V is applied, a leak current flows to a MIS diode before a gate insulating film 109g is broken down. In other words, it is possible to protect the gate insulating film 109g from breakdown.

### Third Embodiment

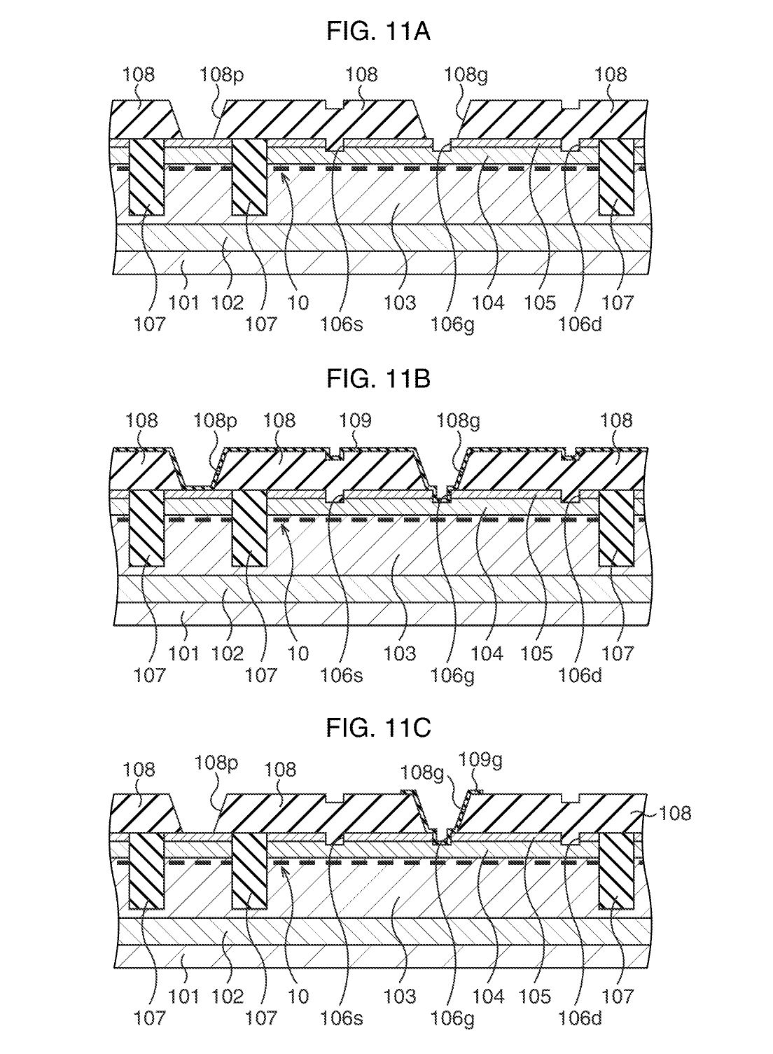

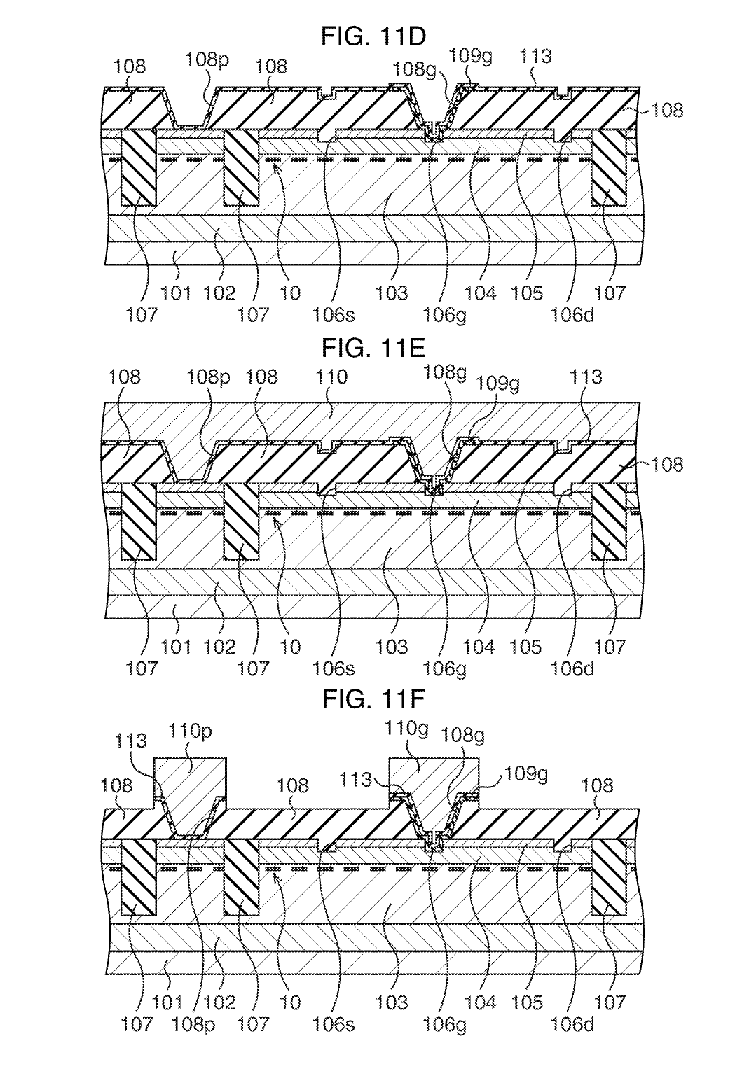

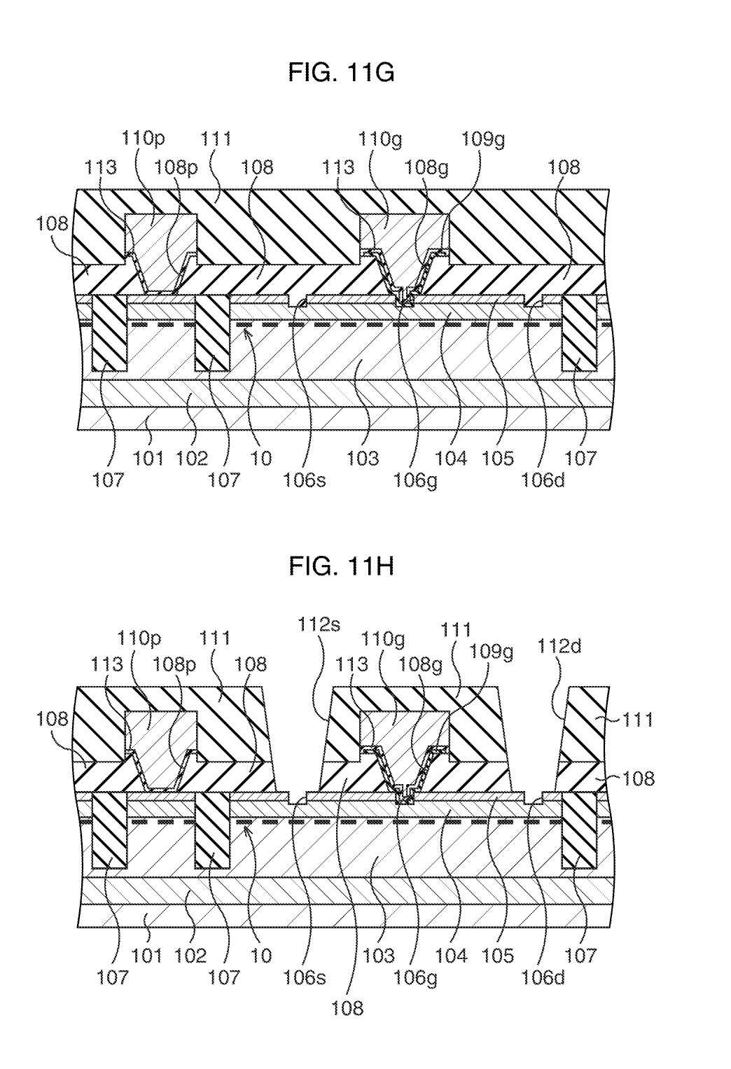

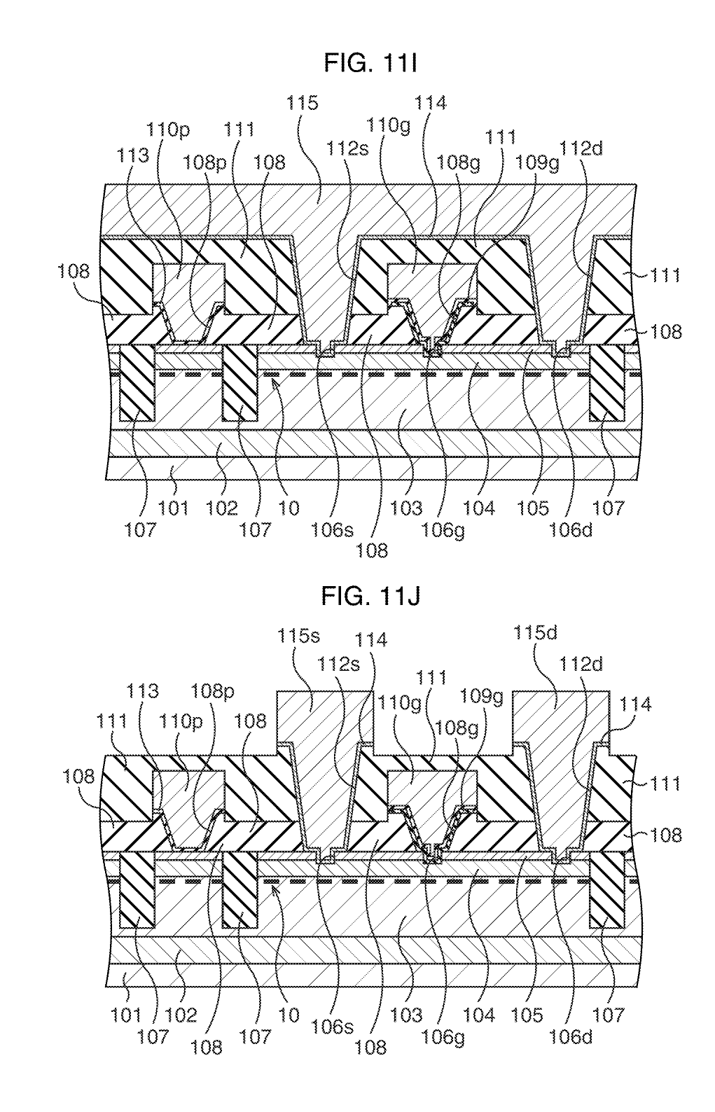

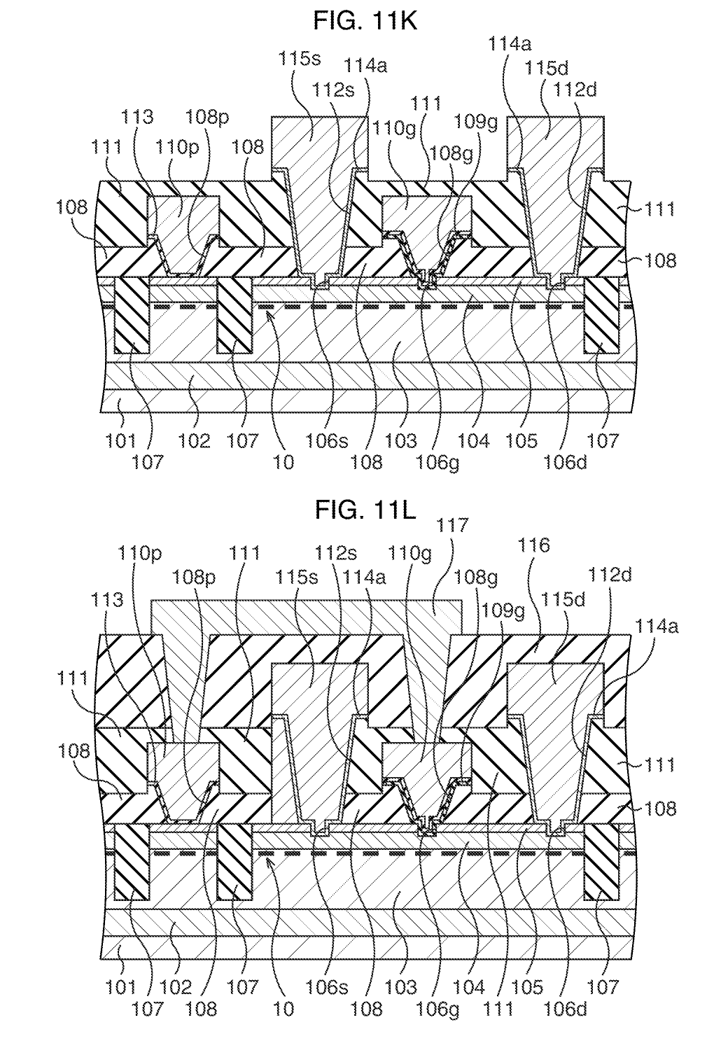

Next, a third embodiment will be described. Also in here, for the sake of convenience, a cross-sectional structure of a semiconductor device is described together with a method for manufacturing the same. Note that explanation of configurations similar to those of the second embodiment, such as a material and a film thickness, is partly omitted. FIG. 11A to FIG. 11L are cross-sectional views depicting a method for manufacturing a semiconductor device according to the third embodiment in order of process steps. In the third embodiment, an electrode of a MIS diode is formed concurrently with a gate electrode of a HEMT, and thereafter, a source electrode and a drain electrode of the HEMT are formed.

First, processings to formation of a protective film 108 are performed similarly to the second embodiment (see FIG. 10F). As illustrated in FIG. 11A, an opening 108g and an opening 108p are each formed in respective regions in which the gate electrode and an electrode of a protective diode are to be formed, of the protective film 108. As illustrated in FIG. 11B, an insulating film 109 to be a gate insulating film is formed on an entire surface. As illustrated in FIG. 11C, the insulating film 109 is patterned thereby to form a gate insulating film 109g. It is preferable to perform an annealing treatment (PDA: post deposition anneal) between formation and patterning of the insulating film 109. In patterning the insulating film 109, for example, a resist pattern covering a region in which the gate insulating film 109g is to be formed and exposing the other part is formed on the insulating film 109, and using this resist pattern as a mask, wet etching using a chemical solution containing fluorine is performed, and the resist pattern is removed.

As illustrated in FIG. 11D, an insulating film 113 of the protective diode (MIS diode) is formed on an entire surface. As illustrated in FIG. 11E, a conductive film 110 to be the gate electrode is formed on an entire surface. As illustrated in FIG. 11F, the conductive film 110 and the insulating film 113 are patterned thereby to form a gate electrode 110g and an electrode 110p for protective diode. In patterning the conductive film 110 and the insulating film 113, a resist pattern covering a region in which the gate electrode 110g is to be formed and a region in which the electrode 110p for protective diode is to be formed and exposing the other part is formed on the conductive film 110, dry etching is performed using this resist pattern as a mask, and the resist pattern is removed. On this occasion, an upper layer part of the protective film 108 is also etched by overetching, and an exposed upper surface of the protective film 108 is planarized. Note that the insulating film 113 below the gate electrode 110g may be also regarded as a part of the gate insulating film.

As illustrated in FIG. 11G, a protective film 111 is formed on an entire surface. As illustrated in FIG. 11H, an opening 112s and an opening 112d are each formed in respective regions in which the source electrode and the drain electrode are to be formed, of the protective film 111 and the protective film 108.

As illustrated in FIG. 11I, a conductive film 114 and a conductive film 115 to be the source electrode and the drain electrode are formed on an entire surface. As illustrated in FIG. 11J, the conductive film 115 and the conductive film 114 are patterned thereby to form a source electrode 115a and a drain electrode 115d. On this occasion, an upper layer part of the protective film 111 may be etched by overetching.

As illustrated in FIG. 11K, an annealing treatment is performed thereby to change the conductive film 114 to a conductive film 114a with a lower contact resistance. As illustrated in FIG. 11L, a protective film 116 is formed on an entire surface. Next, an opening exposing the gate electrode 110g and an opening exposing the electrode 110p for protective diode are formed in the protective film 116 and the protective film 111. Then, a wiring 117 coupling the gate electrode 110g and the electrode 110p for protective diode to each other via those openings is formed. Note that it is preferable that at a time of forming the opening exposing the gate electrode 110g and the opening exposing the electrode 110p for protective diode, an opening exposing the source electrode 115s and an opening exposing the drain electrode 115d are formed, and that at a time of forming the wiring 117, a wiring for a source and a wiring for a drain are also formed.

In the third embodiment also, even if voltage exceeding a breakdown voltage of the gate insulating film 109g is applied to the gate electrode 110g as a surge voltage out of design, a leak current flows to the MIS diode before the gate insulating film 109g is dielectric broken down. In other words, it is possible to protect the gate insulating film 109g from breakdown.

### Fourth Embodiment

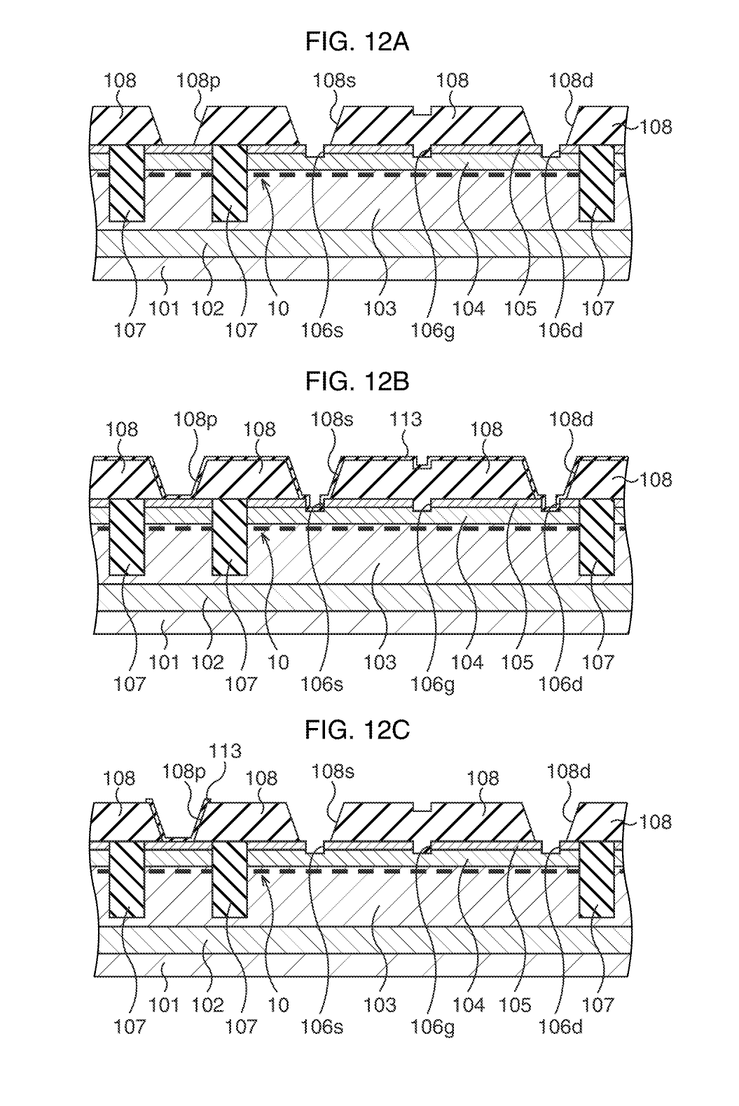

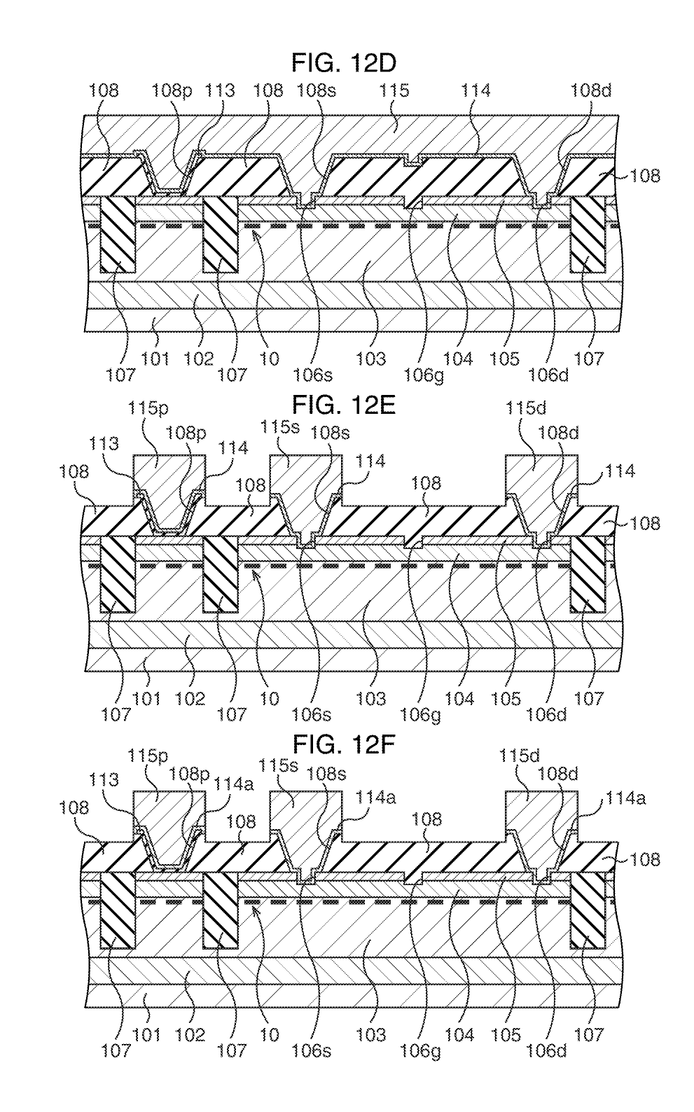

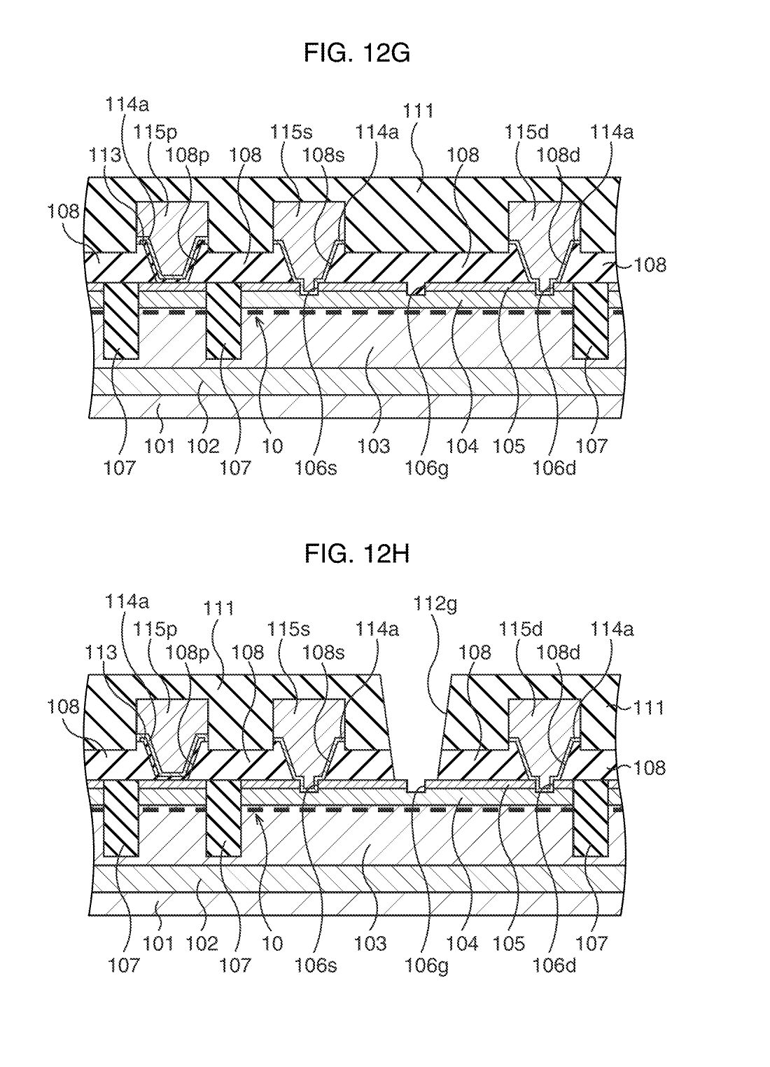

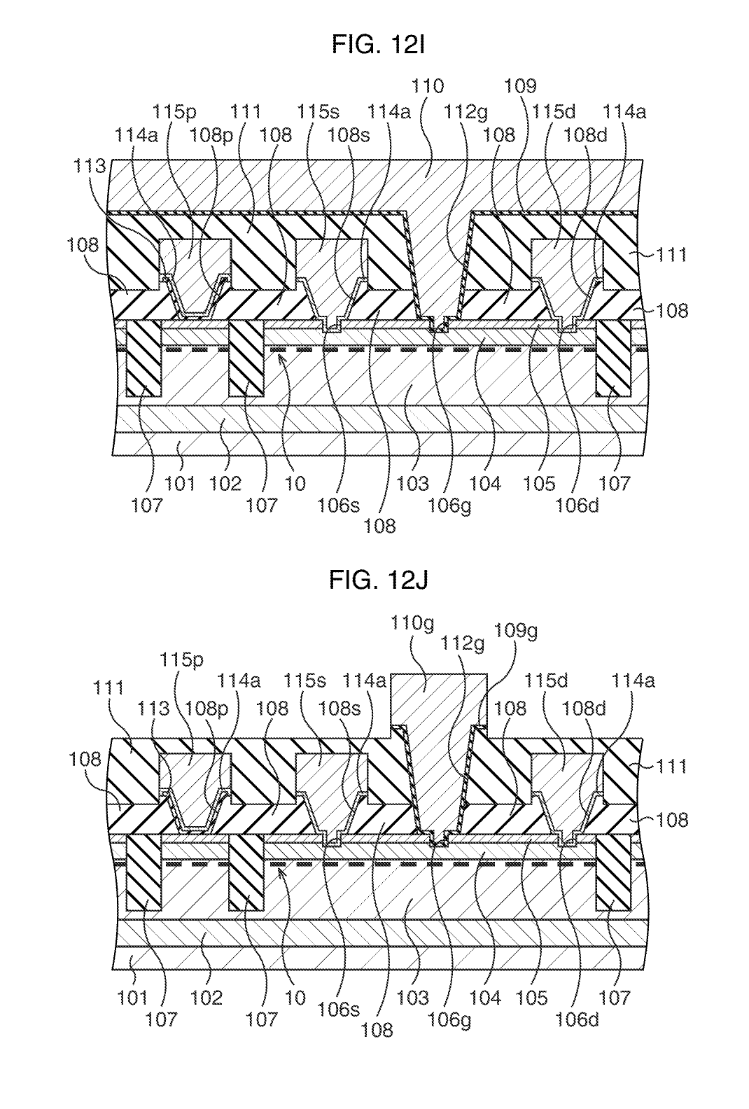

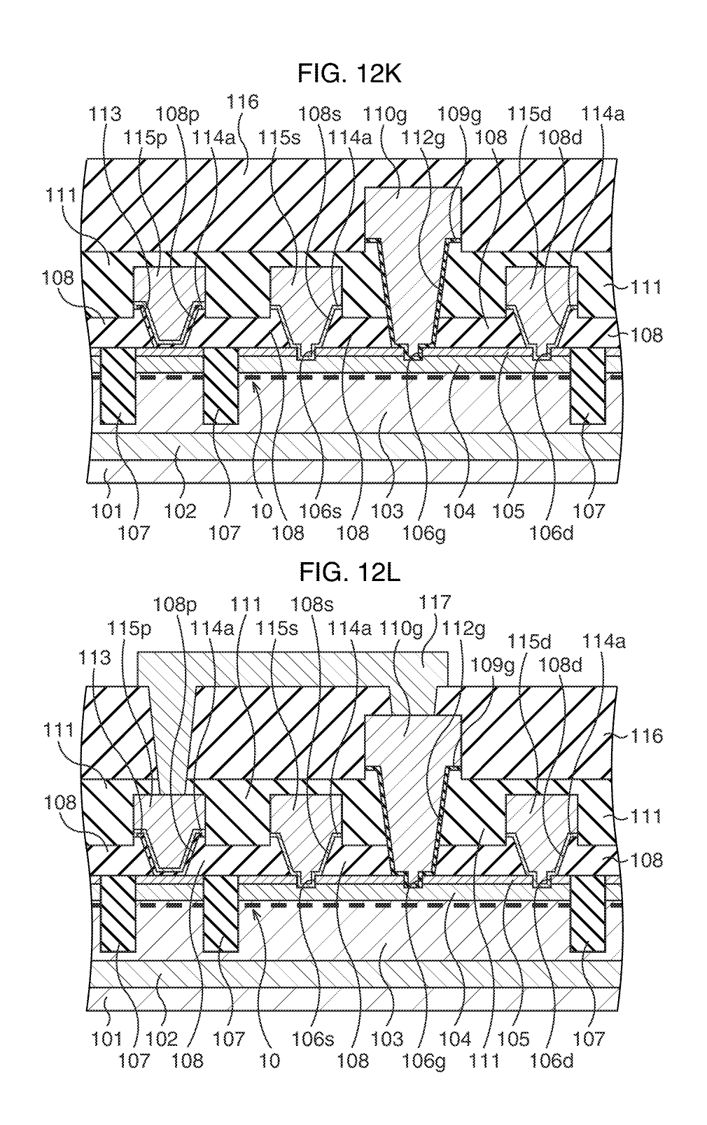

Next, a fourth embodiment will be described. Also in here, for the sake of convenience, a cross-sectional structure of a semiconductor device is described together with a method for manufacturing the same. Note that explanation of configurations similar to those of the second embodiment, such as a material and a film thickness, is partly omitted. FIG. 12A to FIG. 12L are cross-sectional views depicting a method for manufacturing a semiconductor device according to the fourth embodiment in order of process steps. In the fourth embodiment, an electrode of a MIS diode is formed before formation of a gate electrode of a HEMT, concurrently with a source electrode and a drain electrode of the HEMT.

First, processings to formation of a protective film 108 are performed similarly to the second embodiment (see FIG. 10F). As illustrated in FIG. 12A, an opening 108s, an opening 108d and an opening 108p are each formed in respective regions in which the source electrode and the drain electrode, and an electrode of a protective diode are to be formed, of the protective film 108. As illustrated in FIG. 12B, an insulating film 113 of the protective diode (MIS diode) is formed on an entire surface. As illustrated in FIG. 12C, the insulating film 113 is patterned thereby to leave the insulating film 113 only in a region in which the protective diode is to be formed. In patterning the insulating film 113, for example, a resist pattern covering a region in which the insulating film 113 is to be left and exposing the other part is formed on the insulating film 113, and using this resist pattern as a mask, wet etching using a chemical solution containing fluorine is performed, and the resist pattern is removed.

As illustrated in FIG. 12D, a conductive film 114 and a conductive film 115 to be the source electrode, the drain electrode, and the electrode of the protective diode are formed on an entire surface. As illustrated in FIG. 12E, the conductive film 115 and the conductive film 114 are patterned thereby to form a source electrode 115a, a drain electrode 115d, and an electrode 115p for protective diode. On this occasion, an upper layer part of the protective film 108 is also etched by overetching, and an exposed upper surface of the protective film 108 is planarized. As illustrated in FIG. 12F, an annealing treatment is performed thereby to change the conductive film 114 to a conductive film 114a with a lower contact resistance.

As illustrated in FIG. 12G, a protective film 111 is formed on an entire surface. As illustrated in FIG. 12H, an opening 112g is formed in a region in which the gate electrode is to be formed, of the protective film 111 and the protective film 108.

As illustrated in FIG. 12I, an insulating film 109 to be a gate insulating film and a conductive film 110 to be the gate electrode are formed on an entire surface. It is preferable to perform an annealing treatment (PDA: post deposition anneal) between formation of the insulating film 109 and formation of the conductive film 110. As illustrated in FIG. 12J, the conductive film 110 and the insulating film 109 are patterned thereby to form a gate electrode 110g and a gate insulating film 109g. On this occasion, an upper layer part of the protective film 111 may be etched by overetching.

As illustrated in FIG. 12K, a protective film 116 is formed on an entire surface. Subsequently, an opening exposing the gate electrode 110g is formed in the protective film 116, and an opening exposing the electrode 115p for protective diode is formed in the protective film 116 and the protective film 111. Then, as illustrated in FIG. 12L, a wiring 117 coupling the gate electrode 110g and the electrode 115p for protective diode to each other via those openings is formed. Note that it is preferable that at a time of forming the opening exposing the gate electrode 110g and the opening exposing the electrode 115p for protective diode, an opening exposing the source electrode 115s and an opening exposing the drain electrode 115d are also formed, and that at a time of forming the wiring 117, a wiring for a source and a wiring for a drain are also formed.

In the fourth embodiment also, even if a voltage exceeding a breakdown voltage of the gate insulating film 109g is applied to the gate electrode 110g as a surge voltage out of design, a leak current flows to the MIS diode before the gate insulating film 109g is dielectric broken down. In other words, it is possible to protect the gate insulating film 109g from breakdown.

### Fifth Embodiment

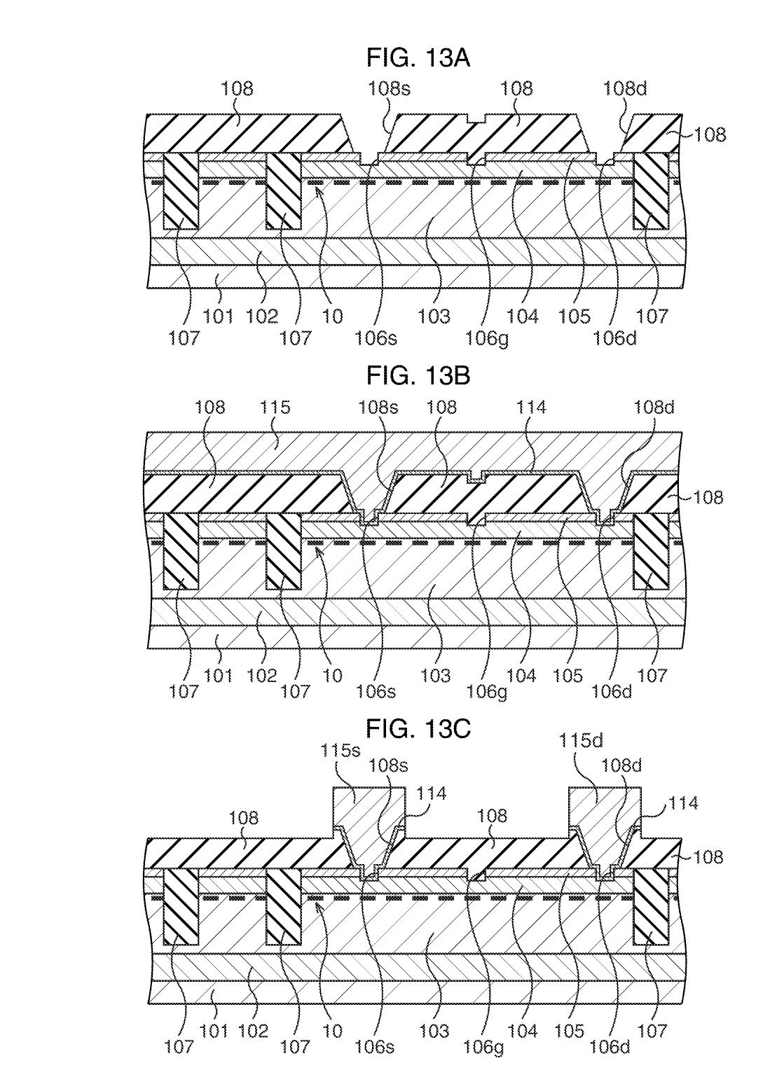

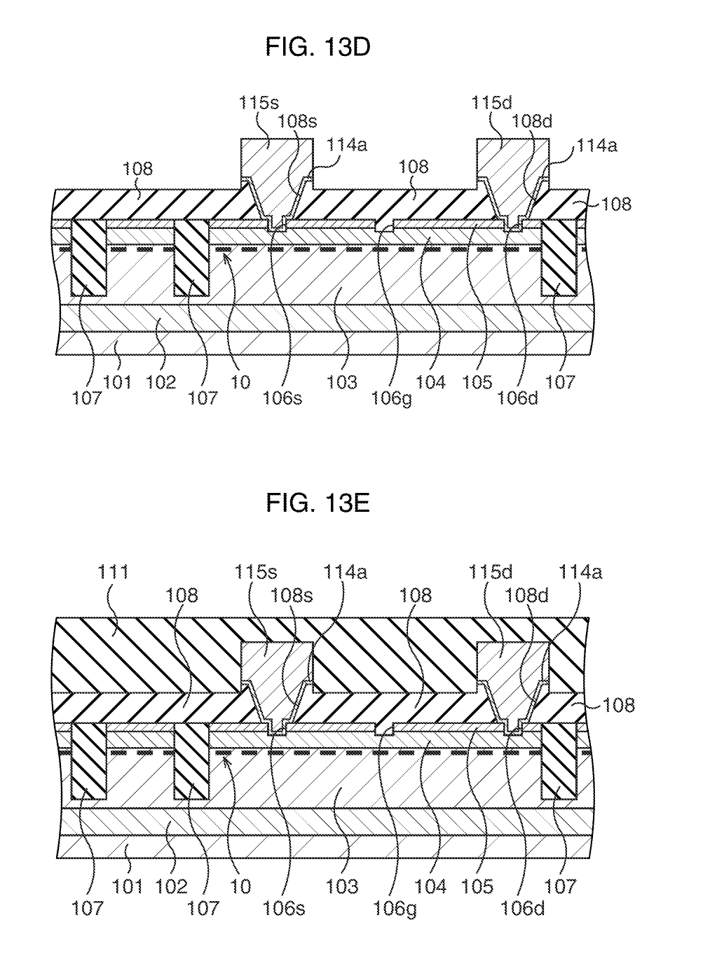

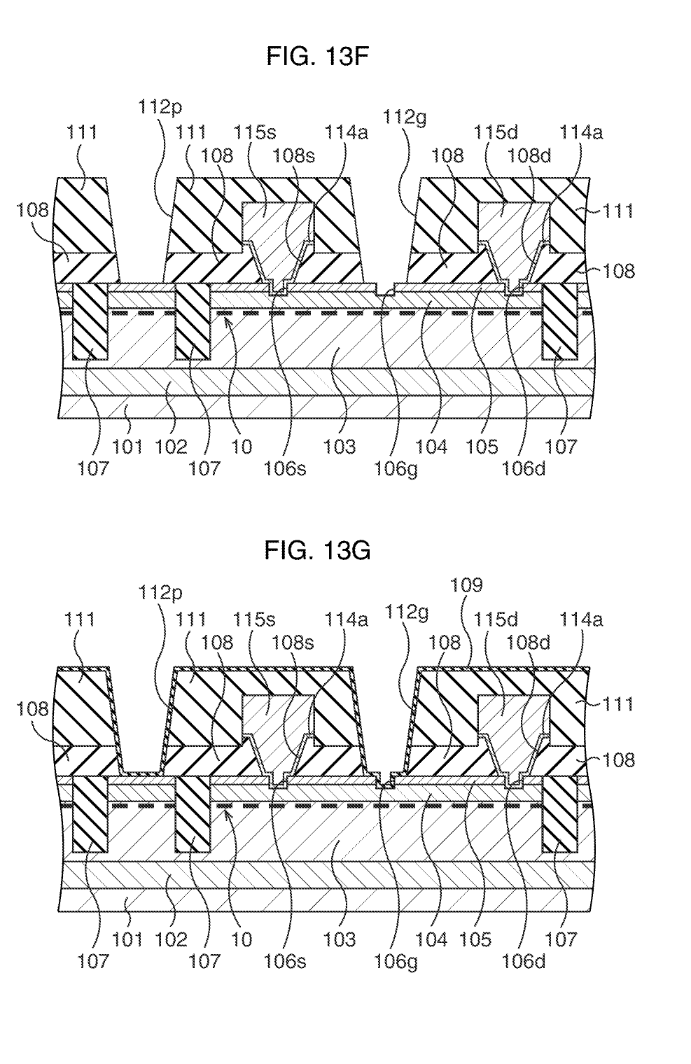

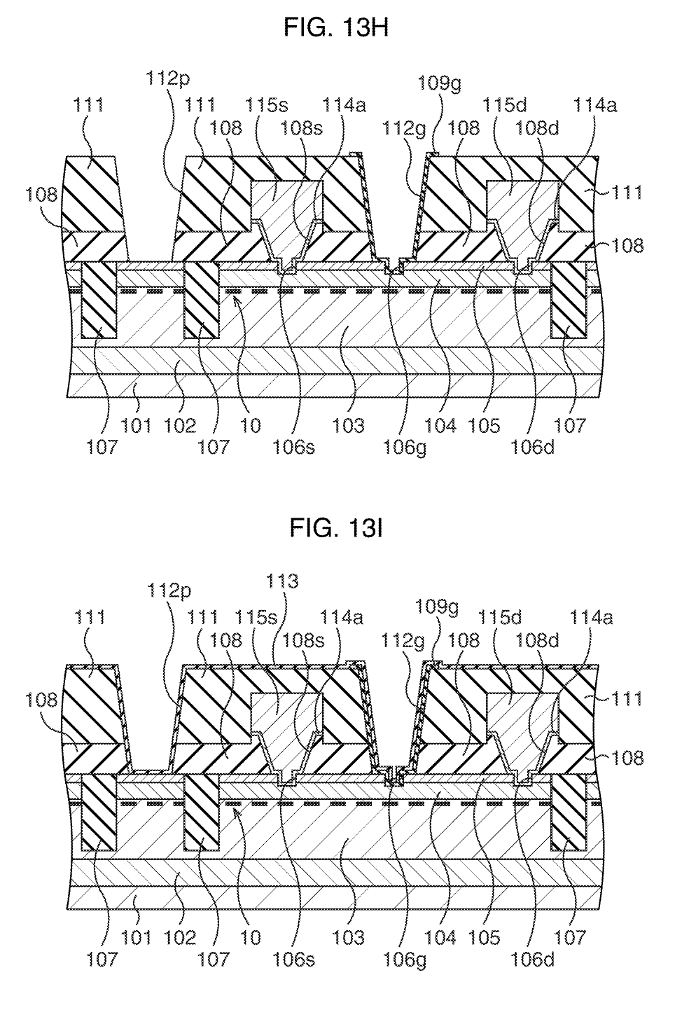

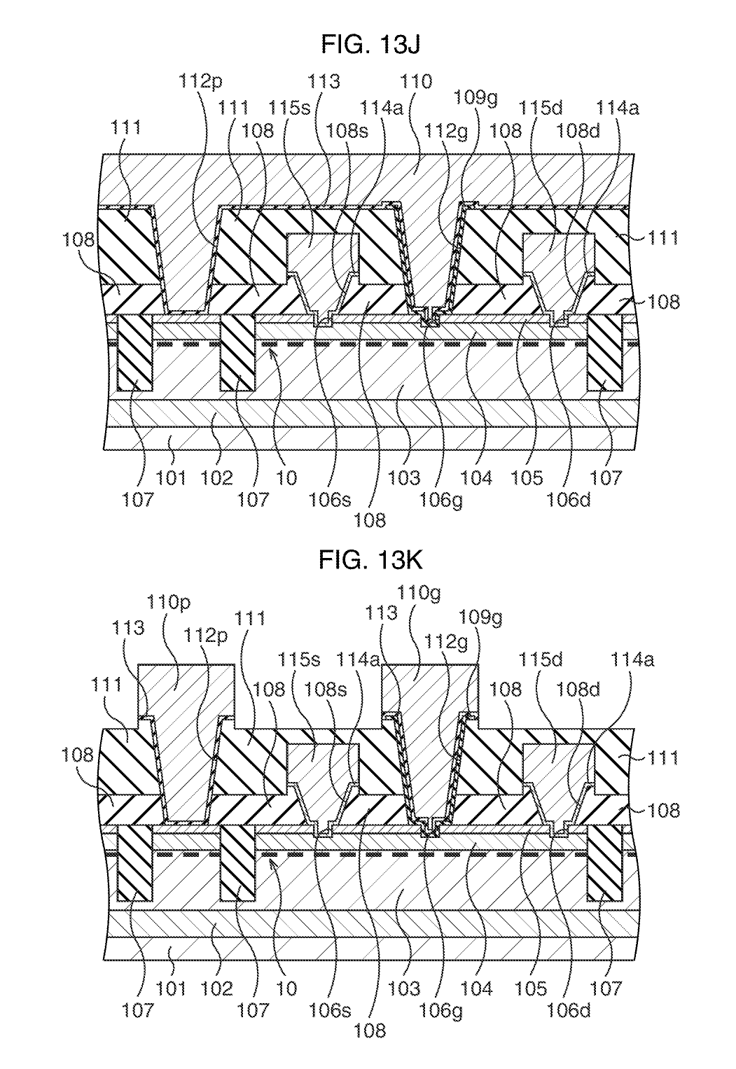

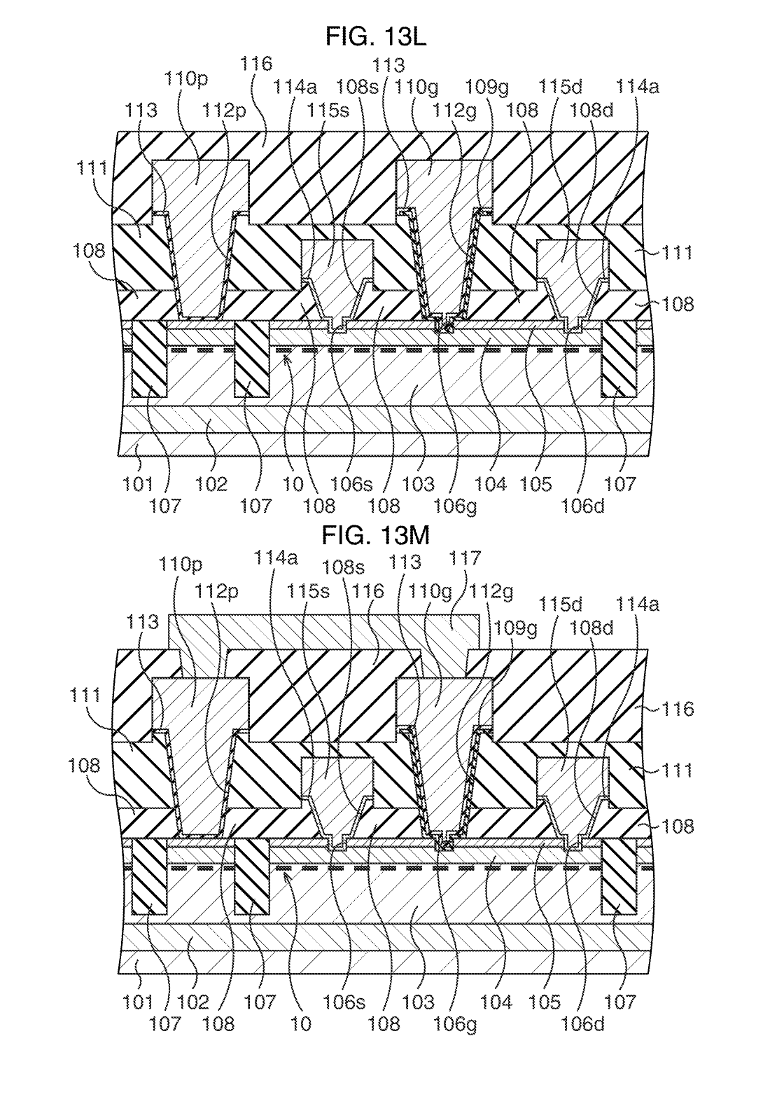

Next, a fifth embodiment will be described. Also in here, for the sake of convenience, a cross-sectional structure of a semiconductor device is described together with a method for manufacturing the same. Note that explanation of configurations similar to those of the second embodiment, such as a material and a film thickness, is partly omitted. FIG. 13A to FIG. 13M are cross-sectional views depicting a method for manufacturing a semiconductor device according to the fifth embodiment in order of process steps. In the fifth embodiment, after a source electrode and a drain electrode of a HEMT are formed, an electrode of a MIS diode is formed concurrently with a gate electrode of the HEMT.

First, processings to formation of a protective film 108 are performed similarly to the second embodiment (see FIG. 10F). As illustrated in FIG. 13A, an opening 108s and an opening 108d are each formed in respective regions in which the source electrode and the drain electrode are to be formed, of the protective film 108. As illustrated in FIG. 13B, a conductive film 114 and a conductive film 115 to be the source electrode and the drain electrode are formed on an entire surface. As illustrated in FIG. 12C, the conductive film 115 and the conductive film 114 are patterned thereby to form a source electrode 115a and a drain electrode 115d. On this occasion, an upper layer part of the protective film 108 is also etched by overetching, and an exposed upper surface of the protective film 108 is planarized.

As illustrated in FIG. 13D, an annealing treatment is performed thereby to change the conductive film 114 to a conductive film 114a with a lower contact resistance. As illustrated in FIG. 13E, a protective film 111 is formed on an entire surface.

As illustrated in FIG. 13F, an opening 112g and an opening 112p are each formed in respective regions in which the gate electrode and a protective diode are to be formed, of the protective film 111 and the protective film 108. As illustrated in FIG. 13G, an insulating film 109 to be a gate insulating film is formed on an entire surface.

As illustrated in FIG. 13H, the insulating film 109 is patterned thereby to form a gate insulating film 109g. It is preferable to perform an annealing treatment (PDA: post deposition anneal) between formation and patterning of the insulating film 109. As illustrated in FIG. 13I, an insulating film 113 of the protective diode (MIS diode) is formed on an entire surface.

As illustrated in FIG. 13J, a conductive film 110 to be the gate electrode is formed on an entire surface. As illustrated in FIG. 13K, the conductive film 110 and the insulating film 113 are patterned thereby to form a gate electrode 110g and an electrode 110p for protective diode. On this occasion, an upper layer part of the protective film 111 may be etched by overetching.

As illustrated in FIG. 13L, a protective film 116 is formed on an entire surface. Thereafter, an opening exposing the gate electrode 110g and an opening exposing the electrode 110p for protective diode are formed in the protective film 116. Then, a wiring 117 coupling the gate electrode 110g and the electrode 110p for protective diode to each other via those openings is formed. Note that it is preferable that at a time of forming the opening exposing the gate electrode 110g and the opening exposing the electrode 110p for protective diode, an opening exposing the source electrode 115s and an opening exposing the drain electrode 115d are also formed, and that at a time of forming the wiring 117, a wiring for a source and a wiring for a drain are also formed.

In the fifth embodiment also, even if a voltage exceeding a breakdown voltage of the gate insulating film 109g is applied to the gate electrode 110g as a surge voltage out of design, a leak current flows to the MIS diode before the gate insulating film 109g is dielectric broken down. In other words, it is possible to protect the gate insulating film 109g from breakdown.

### Sixth Embodiment

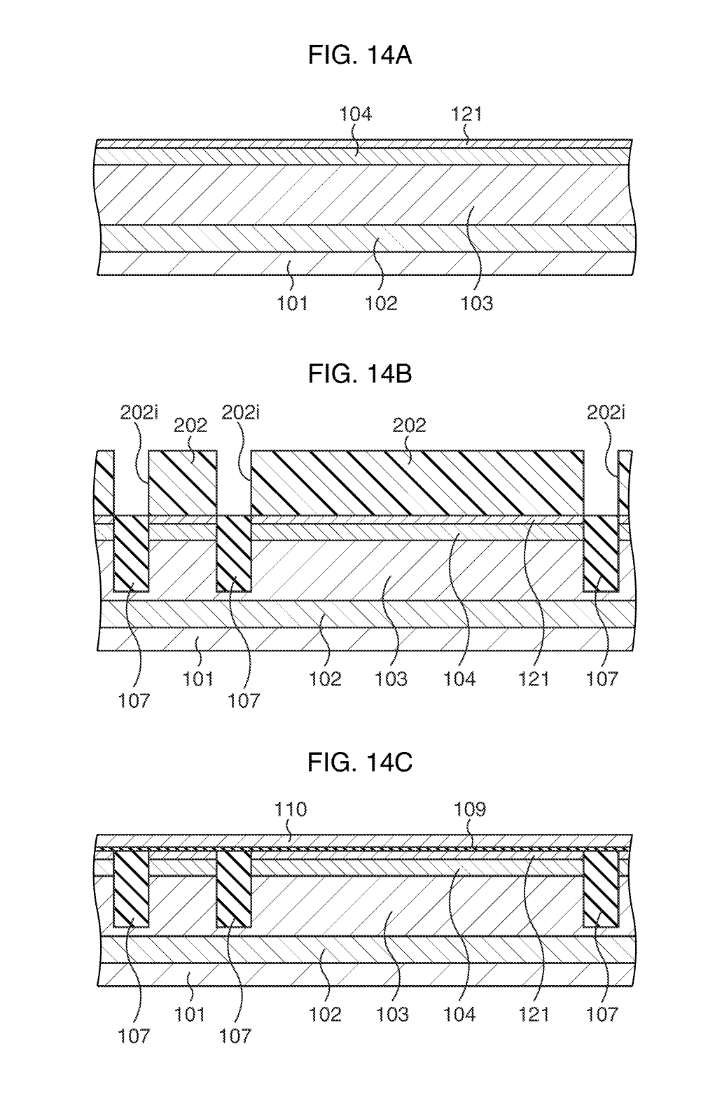

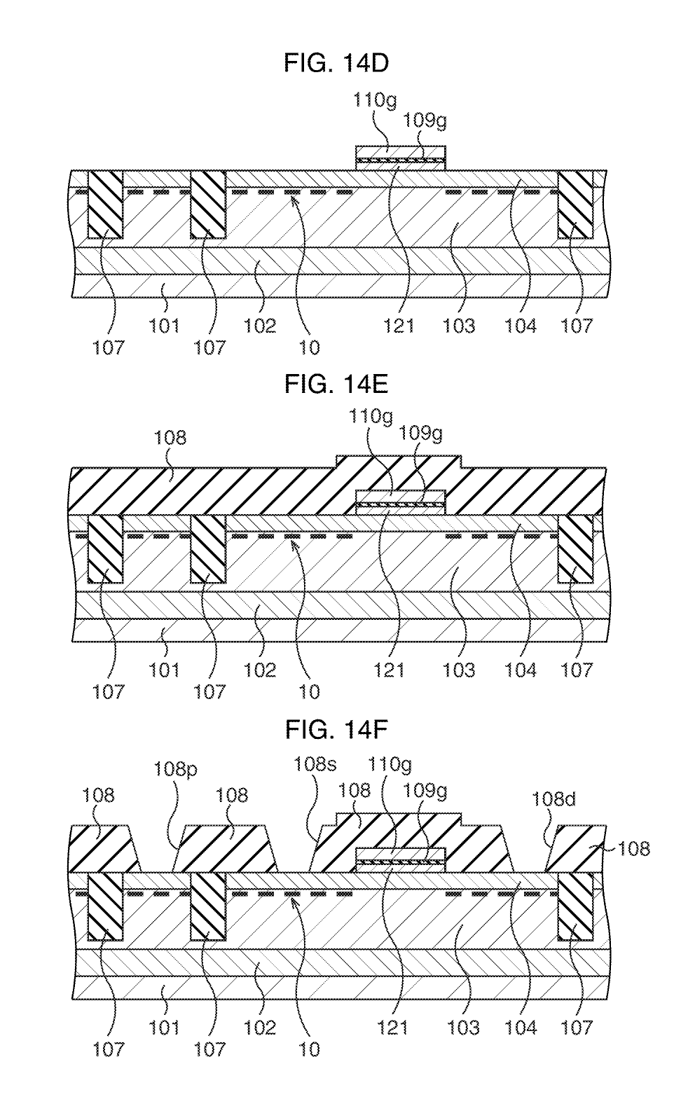

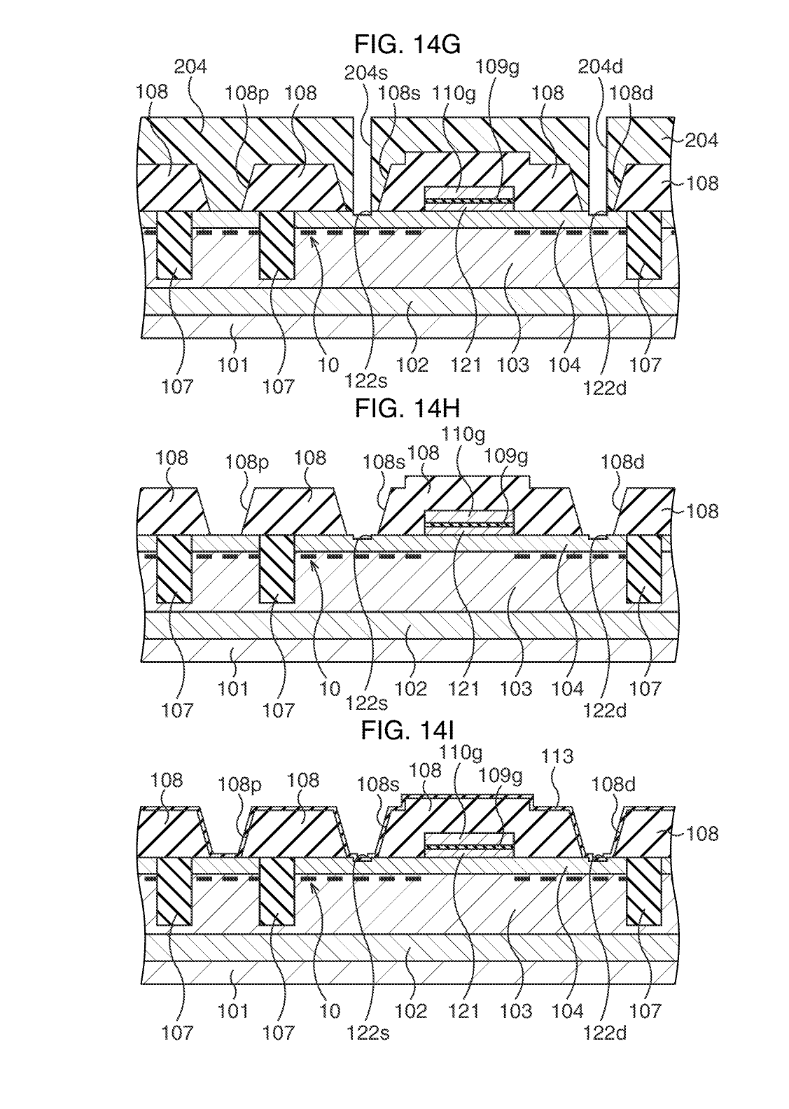

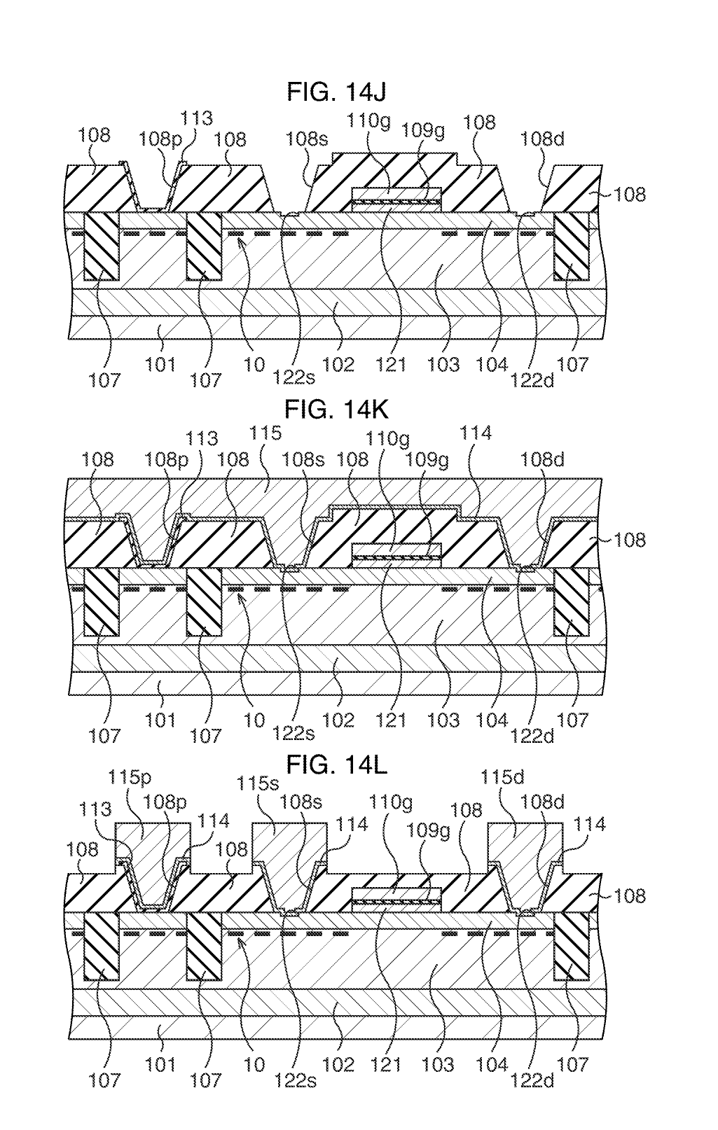

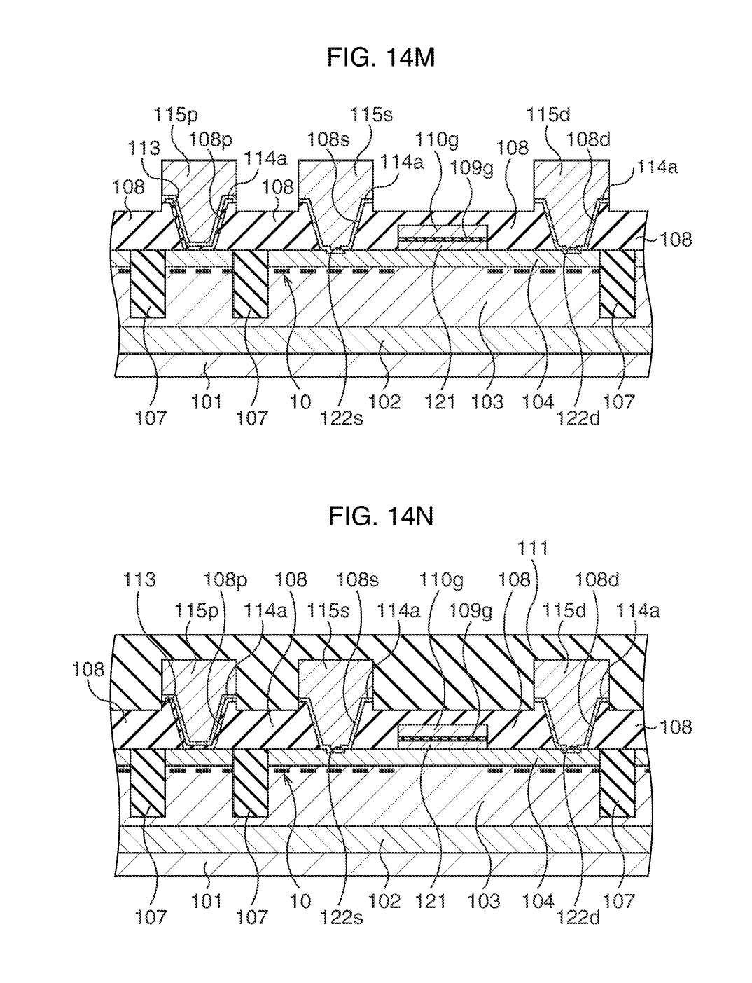

Next, a sixth embodiment will be described. Also in here, for the sake of convenience, a cross-sectional structure of a semiconductor device is described together with a method for manufacturing the same. Note that explanation of configurations similar to those of the second embodiment, such as a material and a film thickness, is partly omitted. FIG. 14A to FIG. 14O are cross-sectional views depicting a method for manufacturing a semiconductor device according to the sixth embodiment in order of process steps. In the sixth embodiment, a 2DEG suppressing layer reducing a two-dimensional electron gas (2DEG) is formed before a gate electrode of a HEMT is formed. Further, an electrode of a MIS diode is formed after formation of the gate electrode of the HEMT, concurrently with a source electrode and a drain electrode of the HEMT.

First, processings to formation of an electron supply layer 104 are performed similarly to the second embodiment (see FIG. 10A). As a result, a two-dimensional electron gas (2DEG) being a carrier occurs in a neighborhood of an interface with an electron supply layer 104, of the electron transit layer 103. As illustrated in FIG. 14A, a 2DEG suppressing layer 121 decreasing the 2DEG is formed on the electron supply layer 104. As a result, the 2DEG having occurred in the neighborhood of the interface with the electron supply layer 104, of the electron transit layer 103 disappears. As the 2DEG suppressing layer 121, for example, a p-type GaN layer with a thickness of about 10 nm to 300 nm is formed. As illustrated in FIG. 14B, a resist pattern 202 having an opening 202i in a region in which an element isolation region is to be formed is formed on the 2DEG suppressing layer 121. Ion implantation is performed using the resist pattern 202 as a mask thereby to form an element isolation region 107. Then, the resist pattern 202 is removed. As illustrated in FIG. 14C, an insulating film 109 to be a gate insulating film and a conductive film 110 to be the gate electrode are formed on an entire surface. Note that it is preferable to perform an annealing treatment (PDA: post deposition anneal) between formation of the insulating film 109 and formation of the conductive film 110.

As illustrated in FIG. 14D, the conductive film 110, the insulating film 109, and the 2DEG suppressing layer 121 are patterned thereby to form a gate electrode 110g and a gate insulating film 109g. As a result, in a region in which the 2DEG suppressing layer has been removed, except in the element isolation region 107, a 2DEG 10 occurs in the neighborhood of the interface with the electron supply layer 104, of the electron transit layer 103 again.

As illustrated in FIG. 14E, a protective film 108 is formed on an entire surface. As illustrated in FIG. 14F, an opening 108s, an opening 108d, and an opening 108p are each formed in respective regions in which the source electrode, the drain electrode, and an electrode of a protective diode are to be formed, of the protective film 108.

As illustrated in FIG. 14G, a resist pattern 204 having openings 204s and 204d respectively in regions in which respective recesses for a source and a drain of the HEMT are to be formed is formed on the protective film 108. Thereafter, using the resist pattern 204 as a mask, the electron supply layer 104 is etched thereby to form a recess 122s for the source and a recess 122d for the drain. In this etching, dry etching is performed, for example, using a parallel flat type etching device, in a chlorine gas atmosphere, with a substrate temperature being 25° C. to 150° C., a pressure being 10 mT to 2 Torr, and an RF power being 50 W to 400 W. Alternatively, dry etching may be performed using an ECR etching device or an ICP etching device, with a pressure being 1 mT to 50 mTorr, and a bias power being 5 W to 80 W. Then, as illustrated in FIG. 14H, the resist pattern 204 is removed. Note that processings from formation to removal of the resist pattern 204 including formation of the recesses 122s and 122d may be omitted. As illustrated in FIG. 14I, an insulating film 113 of the protective diode (MIS diode) is formed on an entire surface.

As illustrated in FIG. 14J, the insulating film 113 is patterned so that the insulating film 113 is left only in a region in which the protective diode is to be formed. As illustrated in FIG. 14K, a conductive film 114 and a conductive film 115 to be the source electrode, the drain electrode, the electrode of the protective diode are formed on an entire surface. As illustrated in FIG. 14L, the conductive film 115 and the conductive film 114 are patterned thereby to form a source electrode 115s, a drain electrode 115d, and an electrode 115p for protective diode. On this occasion, an upper layer part of the protective film 108 is also etched by overetching, so that an exposed upper surface of the protective film 108 is planarized.

As illustrated in FIG. 14M, an annealing treatment is performed thereby to change the conductive film 114 to a conductive film 114a with a lower contact resistance. As illustrated in FIG. 14N, a protective film 111 is formed on an entire surface.

As illustrated in FIG. 14O, an opening exposing the gate electrode 110g is formed in the protective film 111 and the protective film 108, and an opening exposing the electrode 115p for protective diode is formed in the protective film 111. Then, a wiring 117 coupling the gate electrode 110g and the electrode 115p for protective diode to each other via those openings is formed. Note that it is preferable that at a time of forming the opening exposing the gate electrode 110g and the opening exposing the electrode 115p for protective diode, an opening exposing the source electrode 115s and an opening exposing the drain electrode 115d are also formed, and that at a time of forming the wiring 117, a wiring for the source and a wiring for the drain are also formed.

In the sixth embodiment also, even if a voltage exceeding a breakdown voltage of the gate insulating film 109g is applied to the gate electrode 110g as a surge voltage out of design, a leak current flows to the MIS diode before the gate insulating film 109g is dielectric broken down. In other words, it is possible to protect the gate insulating film 109g from breakdown. Further, in the sixth embodiment, since a 2DEG 10 does not exist below the gate electrode 110g, a normally-off operation can be realized.

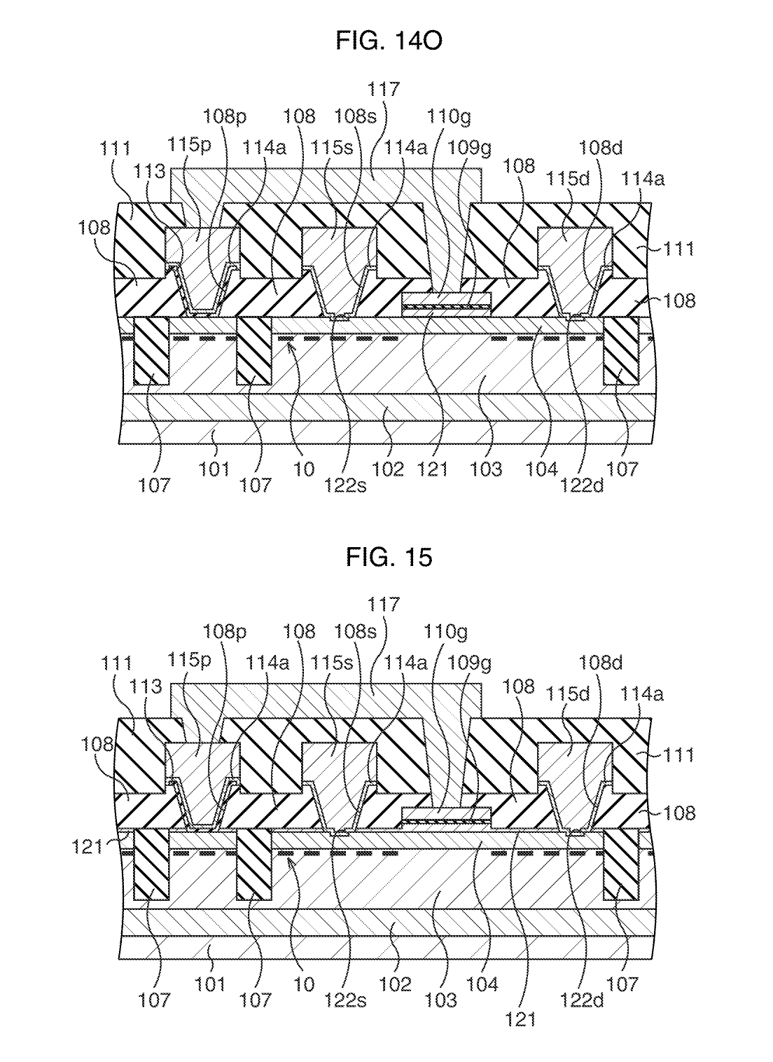

Incidentally, as illustrated in FIG. 15, when a 2DEG is to be generated again, in a region excluding the gate electrode 110g in plan view, thinning of the 2DEG suppressing layer 121 suffices, instead of removing the entire of the 2DEG suppressing layer 121. In such a case, a left part of the 2DEG suppressing layer 121 works similarly to the cap layer 105.

### Seventh Embodiment

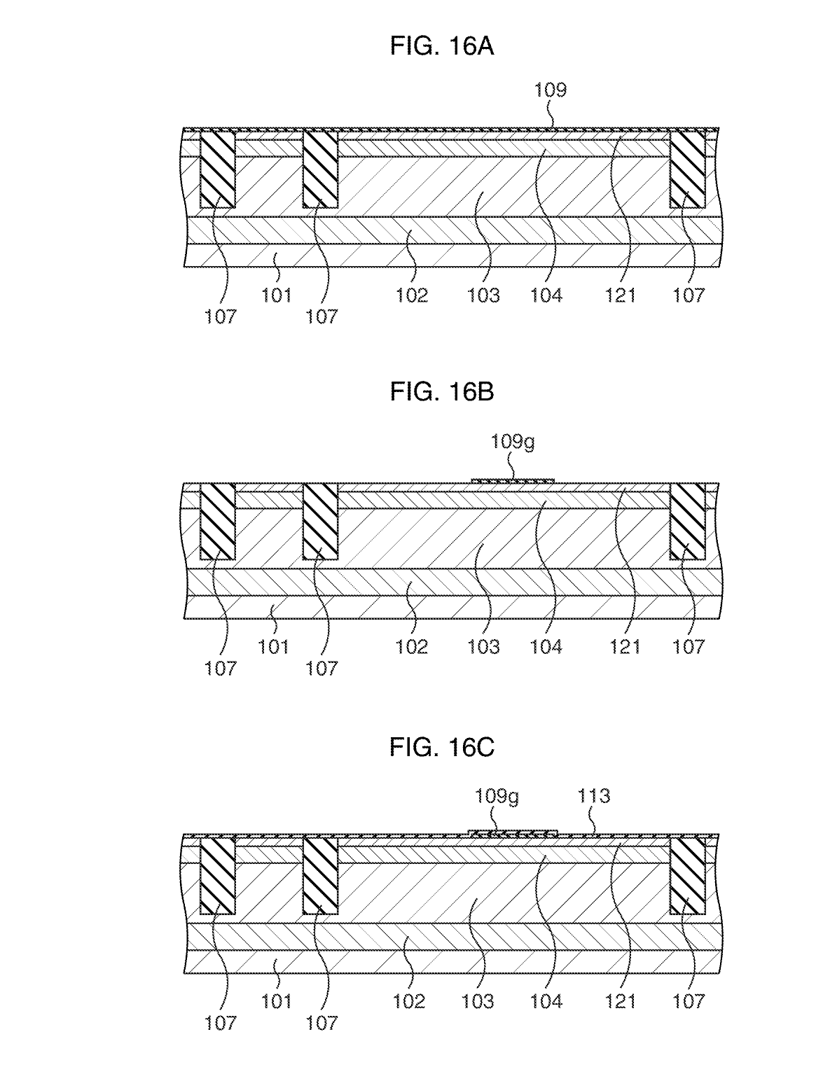

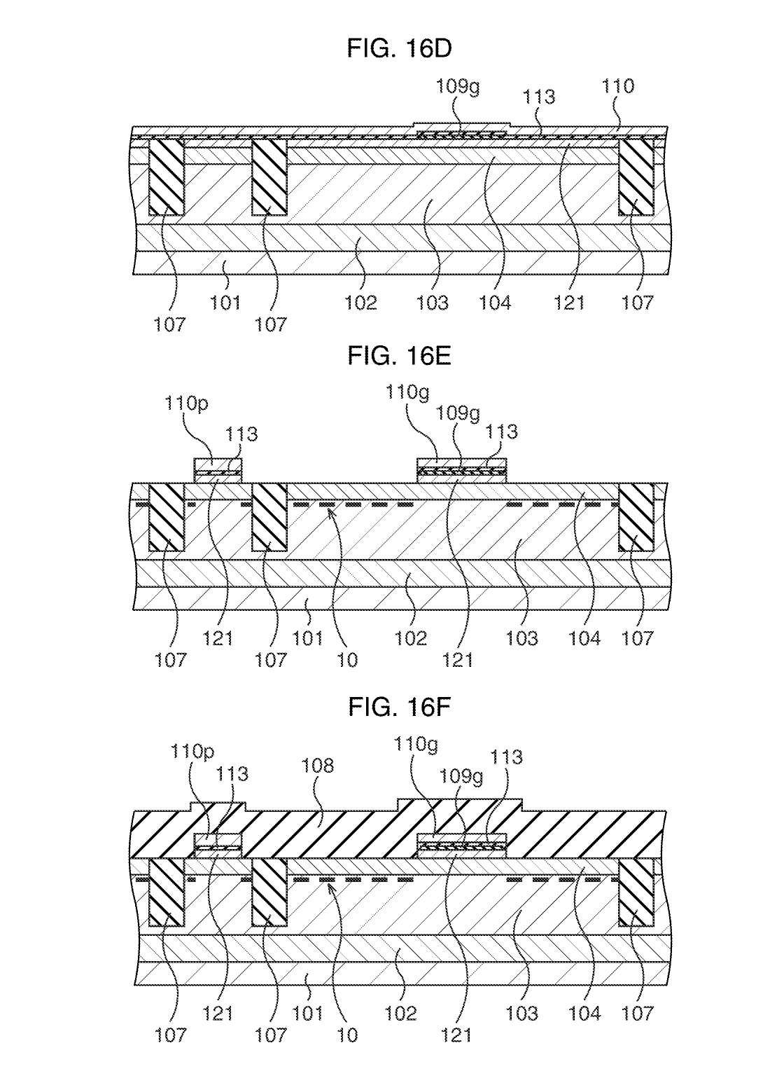

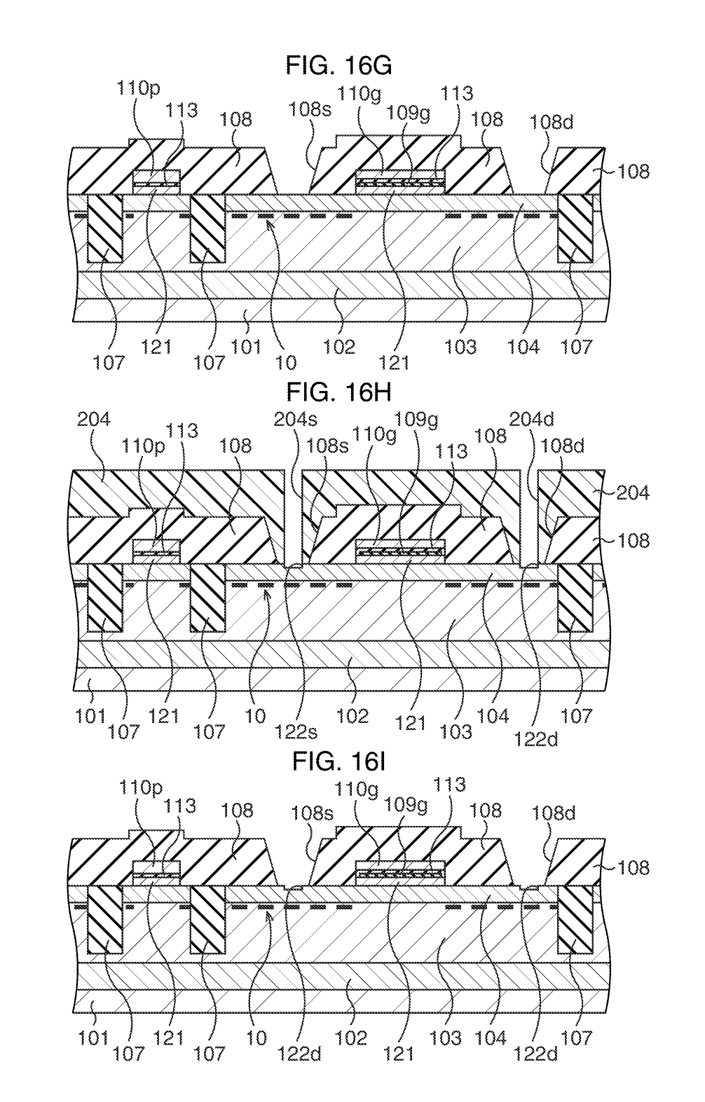

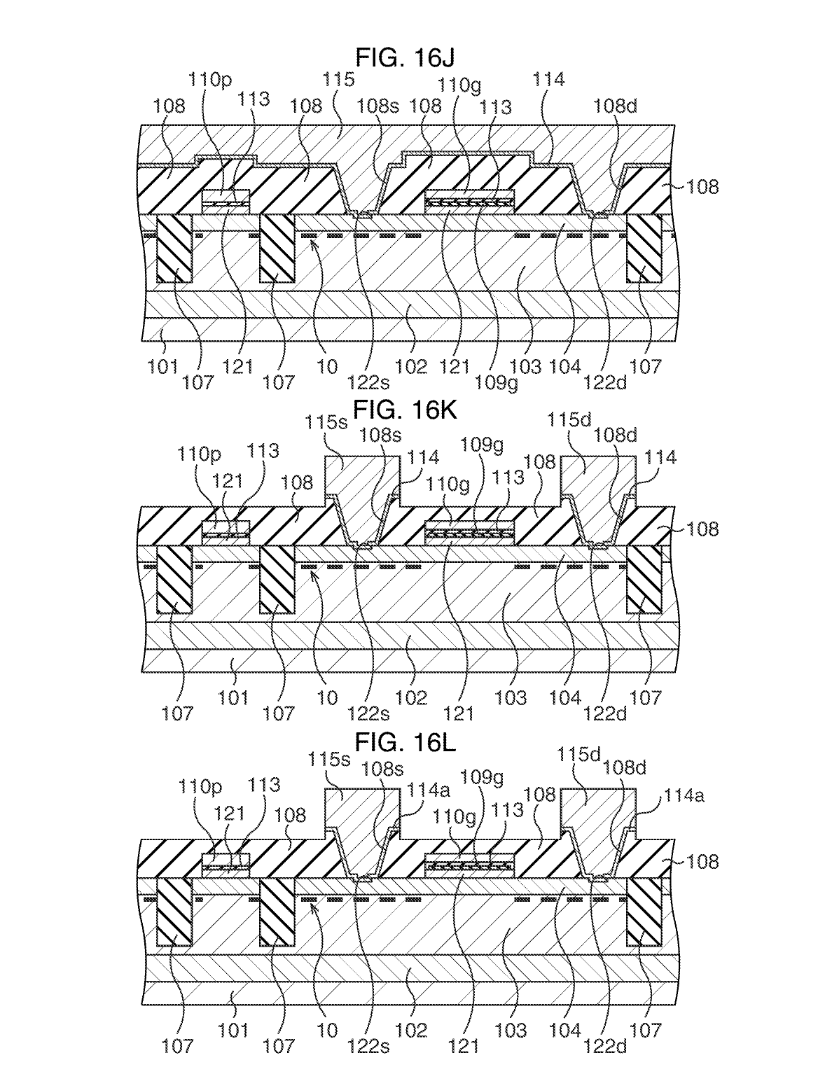

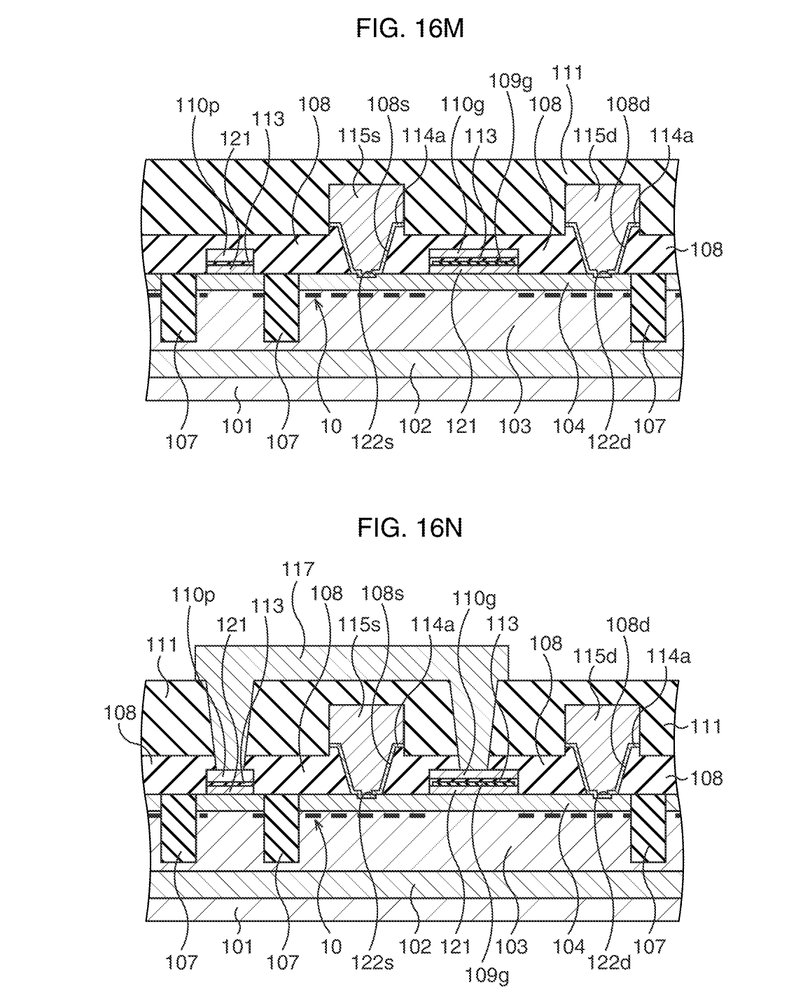

Next, a seventh embodiment will be described. Also in here, for the sake of convenience, a cross-sectional structure of a semiconductor device is described together with a method for manufacturing the same. Note that explanation of configurations similar to those of the second embodiment and the sixth embodiment, such as a material and a film thickness, is partly omitted. FIG. 16A to FIG. 16N are cross-sectional views depicting a method for manufacturing a semiconductor device according to the seventh embodiment in order of process steps. In the seventh embodiment, a 2DEG suppressing layer decreasing a two-dimensional electron gas (2DEG) is formed before a gate electrode of a HEMT is formed. Further, an electrode of a MIS diode is formed concurrently with the gate electrode of the HEMT, and thereafter, a source electrode and a drain electrode of the HEMT are formed.

First, as illustrated in FIG. 16A, processings to formation of an insulating film 109 are performed similarly to the sixth embodiment (see FIG. 14C). As illustrated in FIG. 16B, the insulating film 109 is patterned thereby to form a gate insulating film 109g. It is preferable to perform an annealing treatment (PDA: post deposition anneal) between formation and patterning of the insulating film 109. As illustrated in FIG. 16C, an insulating film 113 of a protective diode (MIS diode) is formed on an entire surface.

As illustrated in FIG. 16D, a conductive film 110 to be the gate electrode is formed on an entire surface. As illustrated in FIG. 16E, the conductive film 110, the insulating film 113, and the 2DEG suppressing layer 121 are patterned thereby to form a gate electrode 110g and an electrode 110p for protective diode. As a result, in a region in which the 2DEG suppressing layer 121 has been removed, except in an element isolation region 107, a 2DEG 10 occurs in a neighborhood of an interface with an electron supply layer 104, of an electron transit layer 103. As illustrated in FIG. 16F, a protective film 108 is formed on an entire surface.

As illustrated in FIG. 16G, an opening 108s and an opening 108d are each formed in respective regions in which the source electrode and the drain electrode are to be formed, of the protective film 108. As illustrated in FIG. 16H, a resist pattern 204 having openings 204s and 204d respectively in a region in which respective recesses for a source and a drain of the HEMT are to be formed is formed on the protective film 108. Thereafter, using the resist pattern 204 as a mask, the electron supply layer 104 is etched thereby to form a recess 122s for the source and a recess 122d for the drain. Then, as illustrated in FIG. 16I, the resist pattern 204 is removed. Note that processings from formation to removal of the resist pattern 204 including formation of the recesses 122s and 122d may be omitted.

As illustrated in FIG. 16J, a conductive film 114 and a conductive film 115 to be the source electrode and the drain electrode are formed on an entire surface. As illustrated in FIG. 16K, the conductive layer 115 and the conductive layer 114 are patterned thereby to form a source electrode 115s and a drain electrode 115d. On this occasion, an upper layer part of the protective film 108 is also etched by overetching, so that an exposed upper surface of the protective film 108 is planarized. As illustrated in FIG. 16L, an annealing treatment is performed thereby to change the conductive film 114 to a conductive film 114a with a lower contact resistance.

As illustrated in FIG. 16M, a protective film 111 is formed on an entire surface. As illustrated in FIG. 16N, an opening exposing the gate electrode 110g and an opening exposing the electrode 110p for protective diode are formed in the protective film 111 and the protective film 108. Then, a wiring 117 coupling the gate electrode 110g and the electrode 110p for protective diode to each other via those openings is formed. Note noted that it is preferable that at a time of forming the opening exposing the gate electrode 110g and the opening exposing the electrode 110p for protective diode, an opening exposing the source electrode 115s and an opening exposing the drain electrode 115d are also formed, and that at a time of forming the wiring 117, a wiring for the source and a wiring for the drain are also formed.

In the seventh embodiment also, even if a voltage exceeding a breakdown voltage of the gate insulating film 109g is applied to the gate electrode 110g as a surge voltage out of design, a leak current flows to the MIS diode before the gate insulating film 109g is dielectric broken down. In other words, it is possible to protect the gate insulating film 109g from breakdown. Further, since a 2DEG 10 does not exist below the gate electrode 110g, a normally-off operation can be realized.

### Eighth Embodiment

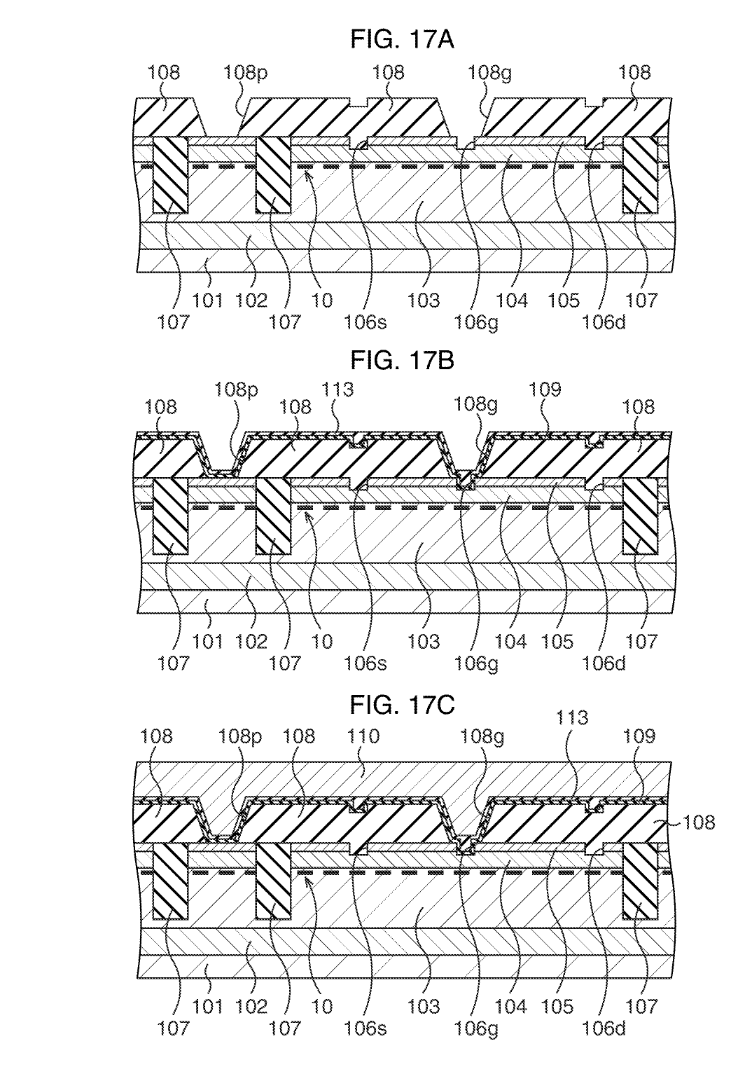

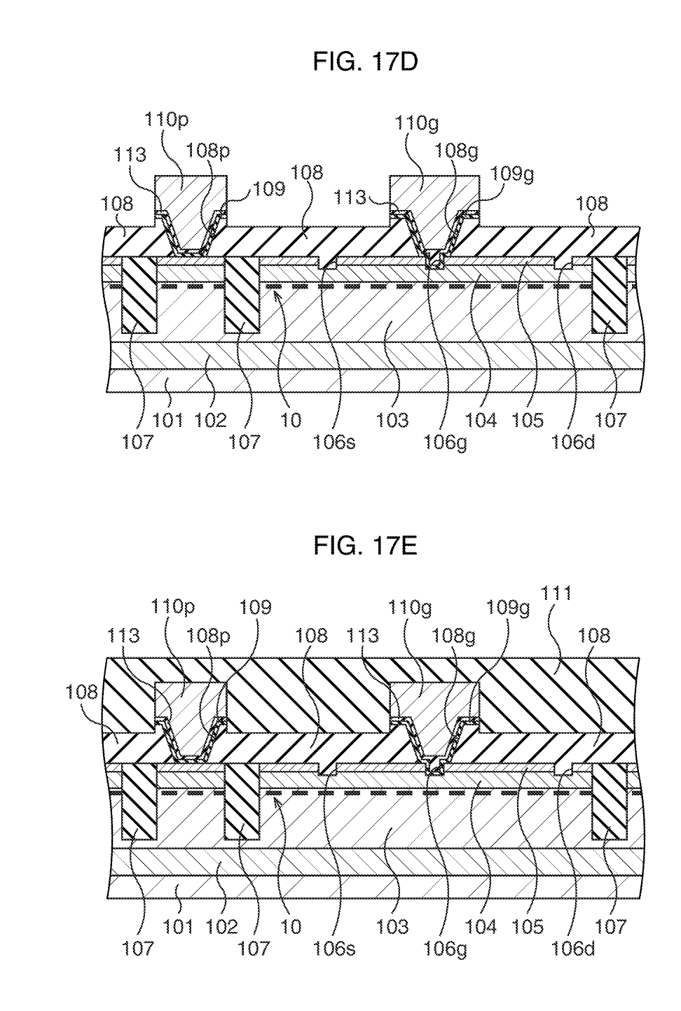

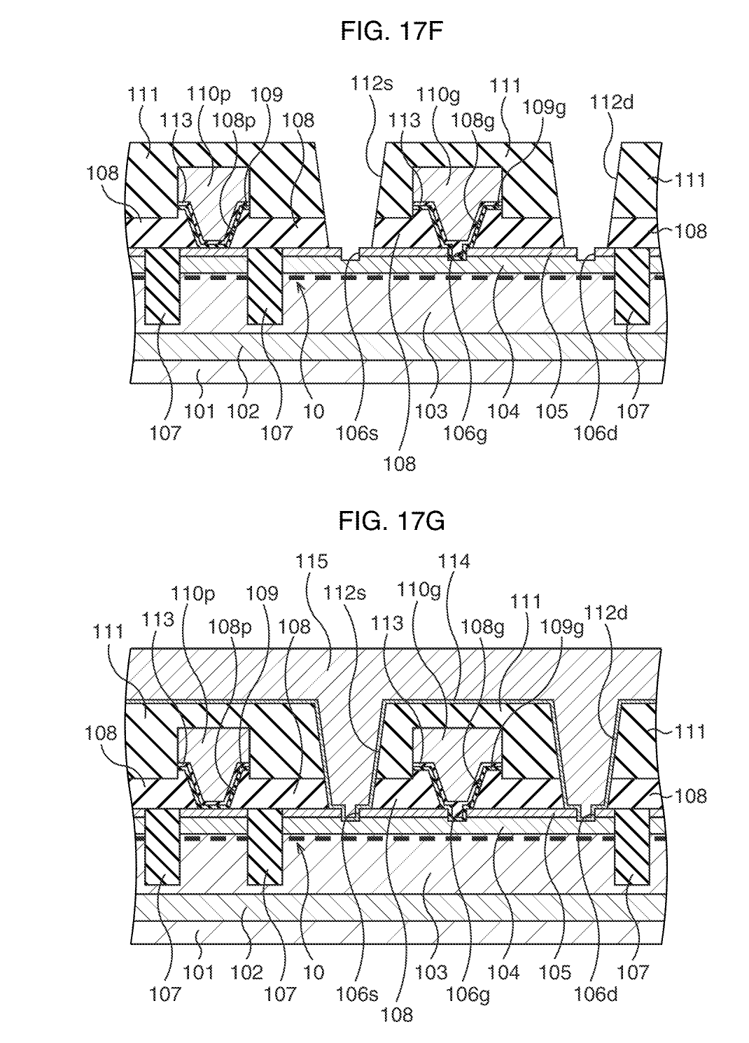

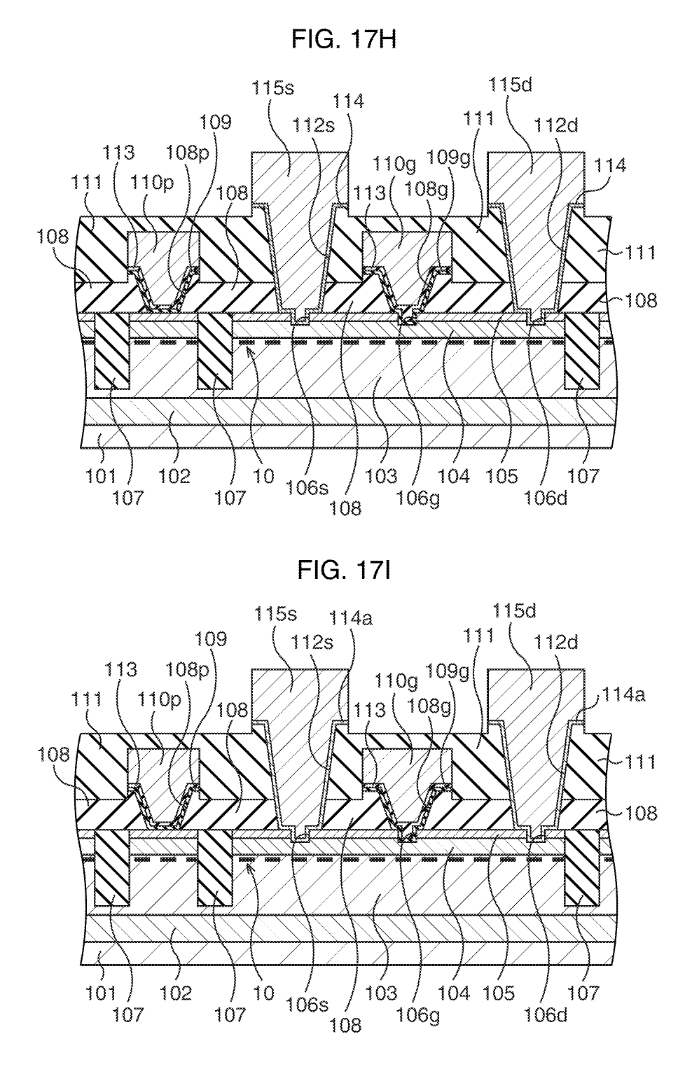

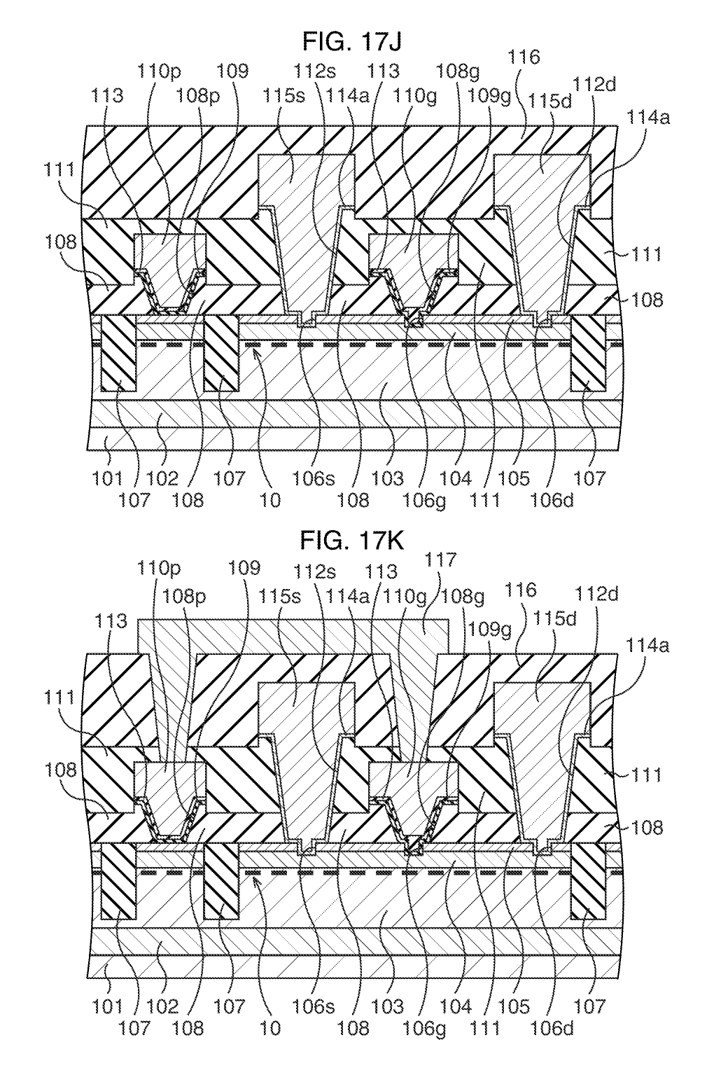

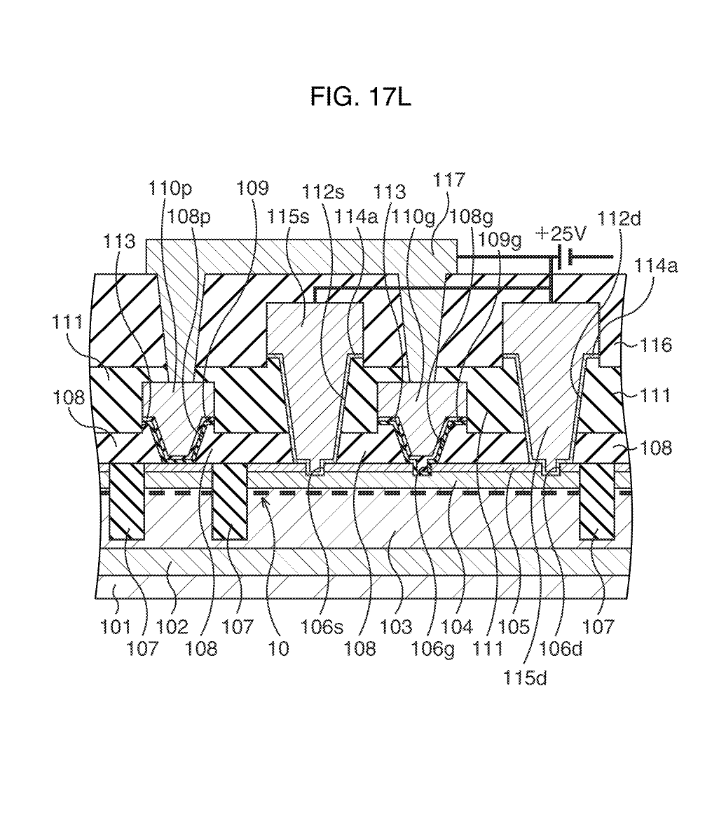

Next, an eighth embodiment will be described. Also in here, for the sake of convenience, a cross-sectional structure of a semiconductor device is described together with a method for manufacturing the same. Note that explanation of configurations similar to those in the second embodiment, such as a material and a film thickness, is partly omitted. FIG. 17A to FIG. 17L are cross-sectional views depicting a method for manufacturing a semiconductor device according to the eighth embodiment in order of process steps. In the eighth embodiment, an electrode of a MIS diode is formed concurrently with a gate electrode of a HEMT, and thereafter, a source electrode and a drain electrode of the HEMT are formed. Further, an insulating film the same as the gate insulating film is placed also between the electrode of the MIS diode and a nitride semiconductor layer, and the insulating film is made broken down.

First, processings to formation of a protective film 108 are performed similarly to the second embodiment (see FIG. 10F). As illustrated in FIG. 17A, an opening 108g is formed in a region in which the gate electrode is to be formed and an opening 108p is formed in a region in which an electrode of a protective diode is to be formed, of the protective film 108. As illustrated in FIG. 17B, an insulating film 109 to be a gate insulating film is formed on an entire surface, and an insulating film 113 of the protective diode (MIS diode) is formed thereon. It is preferable to perform an annealing treatment (PDA: post deposition anneal) between formation of the insulating film 109 and formation of the insulating film 113. As illustrated in FIG. 17C, a conductive film 110 to be the gate electrode is formed on the insulating film 113.

As illustrated in FIG. 17D, the conductive film 110, the insulating film 113, and the insulating film 109 are patterned thereby to form a gate electrode 110g and a gate insulating film 109g and to form an electrode 110p for protective diode. On this occasion, an upper layer part of the protective film 108 is also etched by overetching, and an exposed upper surface of the protective film 108 is planarized. The insulating film 113 below the gate electrode 110g may be regarded as a part of the gate insulating film. As illustrated in FIG. 17E, a protective film 111 is formed on an entire surface.

As illustrated in FIG. 17F, an opening 112s and an opening 112d are each formed in respective regions in which the source electrode and the drain electrode are to be formed, of the protective film 111 and the protective film 108. As illustrated in FIG. 17G, a conductive film 114 and a conductive film 115 to be the source electrode and the drain electrode are formed on an entire surface.

As illustrated in FIG. 17H, the conductive film 115 and the conductive film 114 are patterned thereby to form a source electrode 115s and a drain electrode 115d. On this occasion, an upper layer part of the protective film 111 may be etched by overetching. As illustrated in FIG. 17I, an annealing treatment is performed thereby to change the conductive film 114 to a conductive film 114a with a lower contact resistance.

As illustrated in FIG. 17J, a protective film 116 is formed on an entire surface. As illustrated in FIG. 17K, an opening exposing the gate electrode 110g and an opening exposing the electrode 110p for protective diode are formed in the protective film 116 and the protective film 111. Then, a wiring 117 coupling the gate electrode 110g and the electrode 110p for protective diode to each other via those openings is formed. Note that it is preferable that at a time of forming the opening exposing the gate electrode 110g and the opening exposing the electrode 110p for protective diode, an opening exposing the source electrode 115s and an opening exposing the drain electrode 115d are also formed, and that at a time of forming the wiring 117, a wiring for a source and a wiring for a drain are also formed.

As illustrated in FIG. 17L, in a state that the gate electrode 110g, the source electrode 115s, and the drain electrode 115d are short-circuited, a voltage equal to or more than a breakdown voltage of the insulating film 109, for example, +25 V, is applied to the electrode 110p for protective diode from the outside. As a result, the insulating film 109 below the electrode 110p for protective diode is made broken down. On this occasion, the insulating film 113 below the electrode 110p for protective diode is not broken down, and functions as an insulating film of the MIS diode.

In the eighth embodiment also, even if a voltage exceeding a breakdown voltage of the gate insulating film 109g is applied to the gate electrode 110g as a surge voltage out of design, a leak current flows to the MIS diode before the gate insulating film 109g is broken down. In other words, it is possible to protect the gate insulating film 109g from breakdown.

### Ninth Embodiment

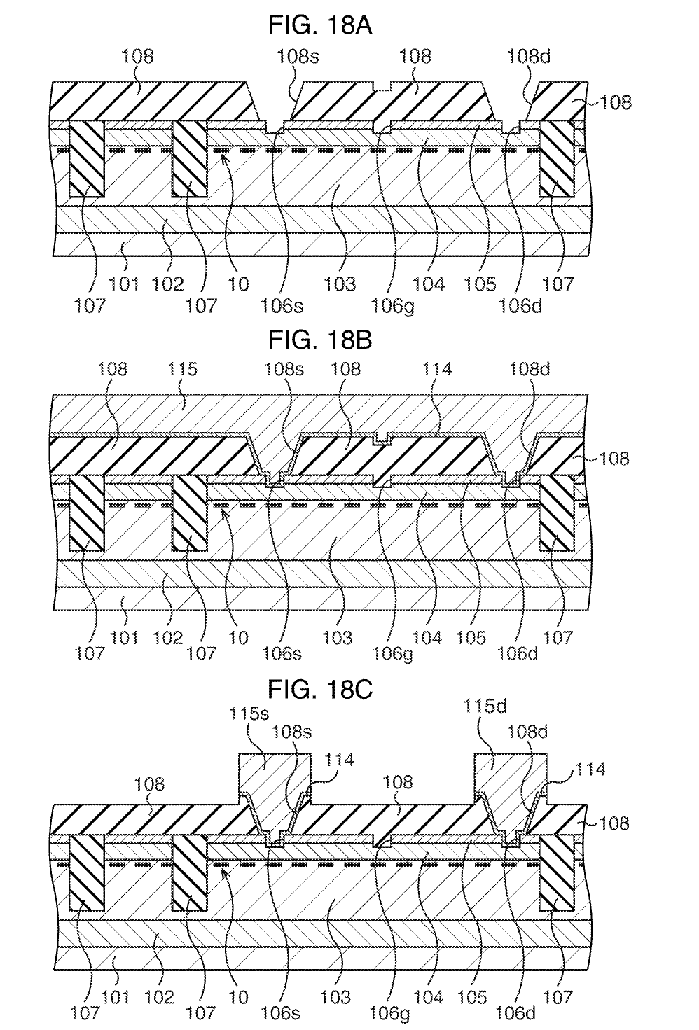

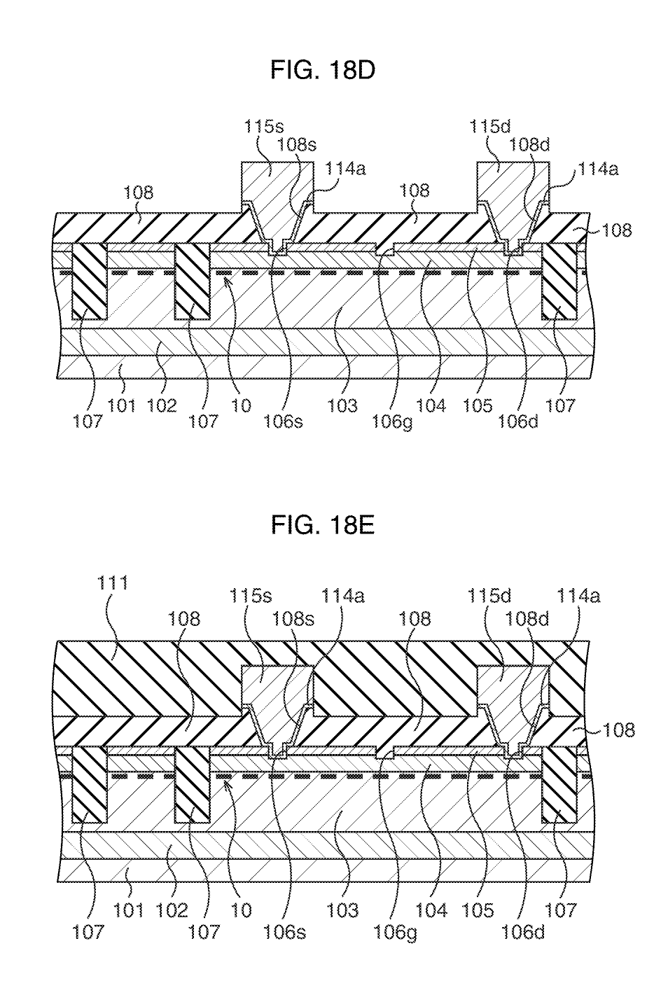

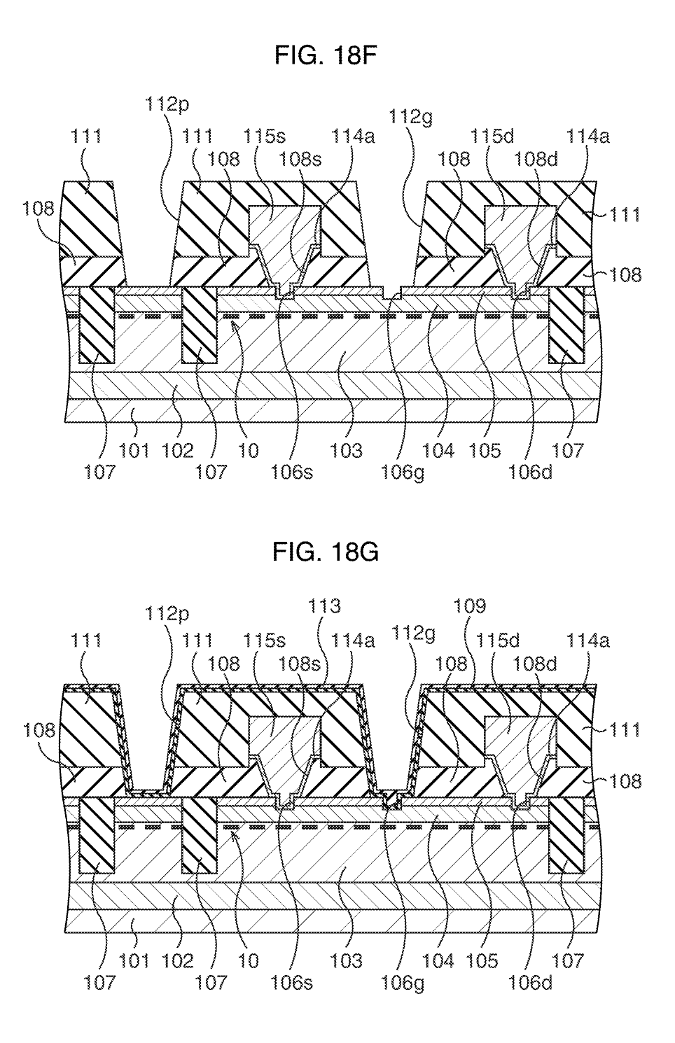

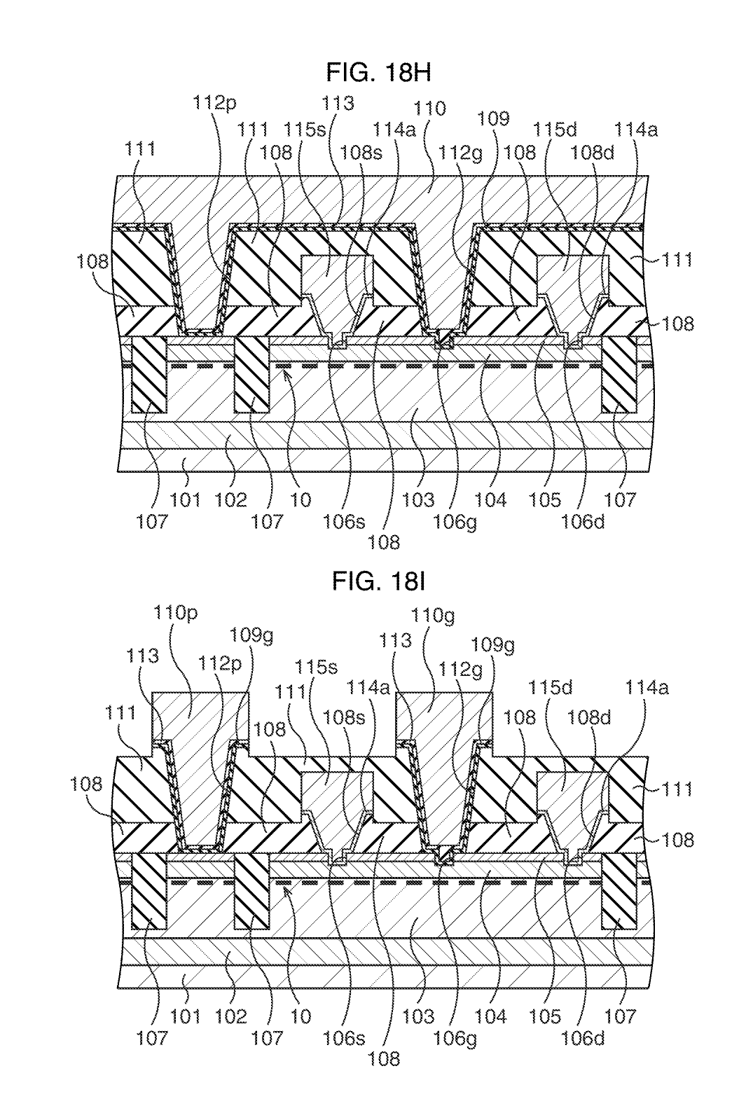

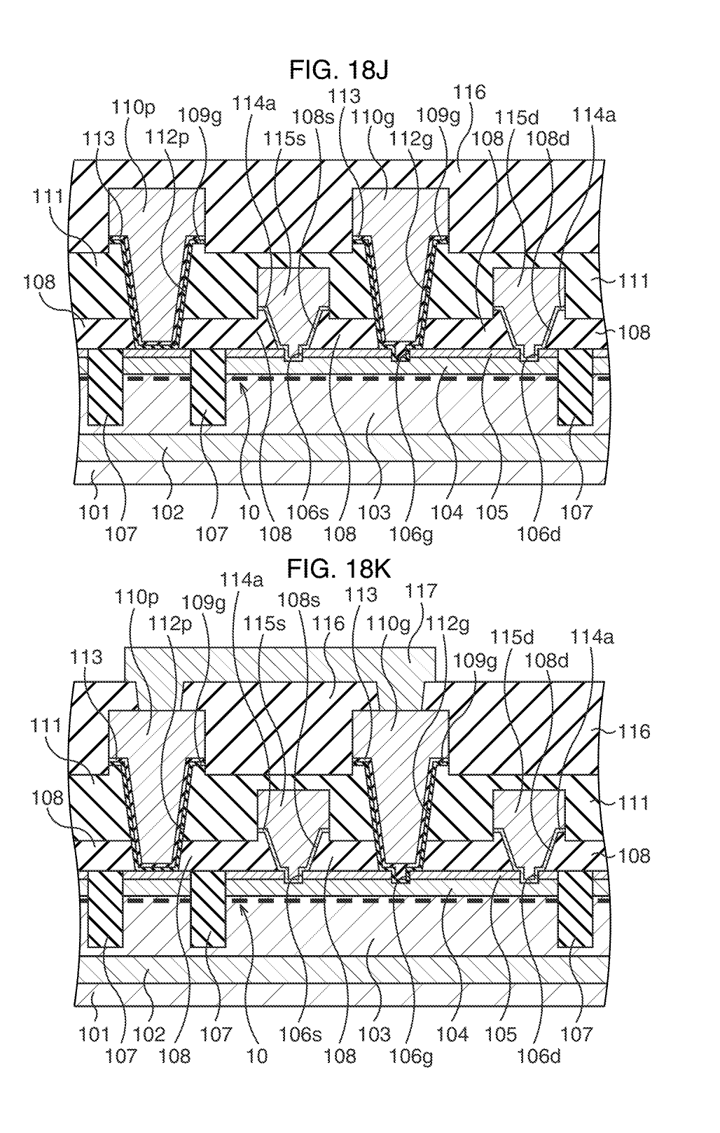

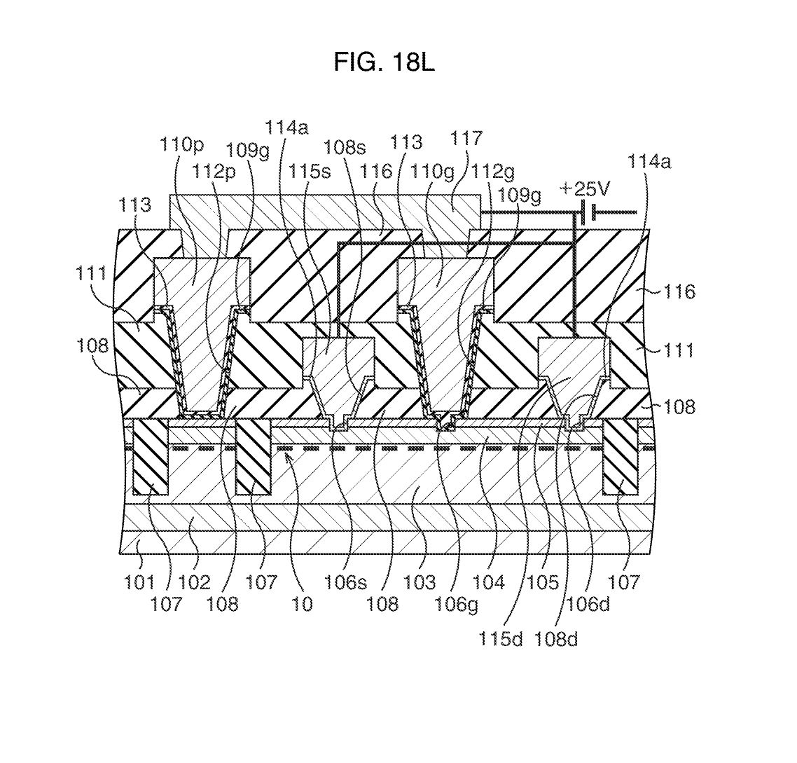

Next, a ninth embodiment will be described. Also in here, for the sake of convenience, a cross-sectional structure of a semiconductor device is described together with a method for manufacturing the same. Note that explanation of configurations similar to those of the second embodiment, such as a material and a film thickness, is partly omitted. FIG. 18A to FIG. 18L are cross-sectional views depicting a method for manufacturing a semiconductor device according to the ninth embodiment in order of process steps. In the ninth embodiment, after a source electrode and a drain electrode of a HEMT are formed, an electrode of a MIS diode is formed concurrently with a gate electrode of the HEMT.

Further, an insulating film the same as a gate insulating film is placed also between the electrode of the MIS diode and a nitride semiconductor layer, and the insulating film is made broken down.

First, processings to formation of a protective film 108 are performed similarly to the second embodiment (see FIG. 10F). As illustrated in FIG. 18A, an opening 108s and an opening 108d are each formed in respective regions in which the source electrode and the drain electrode are to be formed, of the protective film 108. As illustrated in FIG. 18B, a conductive film 114 and a conductive film 115 to be the source electrode and the drain electrode are formed on an entire surface. As illustrated in FIG. 18C, the conductive film 115 and the conductive film 114 are patterned thereby to form a source electrode 115s and a drain electrode 115d. On this occasion, an upper layer part of the protective film 108 is also etched by overetching, so that an exposed upper surface of the protective film 108 is planarized.

As illustrated in FIG. 18D, an annealing treatment is performed thereby to change the conductive film 114 to a conductive film 114a with a lower contact resistance. As illustrated in FIG. 18E, a protective film 111 is formed on an entire surface.

As illustrated in FIG. 18F, an opening 112g and an opening 112p are each formed in respective regions in which the gate electrode and a protective diode are to be formed, of the protective film 111 and the protective film 108. As illustrated in FIG. 18G, an insulating film 109 to be a gate insulating film is formed on an entire surface, and an insulating film 113 of the protective diode (MIS diode) is formed thereon. It is preferable to perform an annealing treatment (PDA: post deposition anneal) between formation of the insulating film 109 and formation of the insulating film 113.

As illustrated in FIG. 18H, a conductive film 110 to be the gate electrode is formed on the insulating film 113. As illustrated in FIG. 18I, the conductive film 110, the insulating film 113, and the insulating film 109 are patterned thereby to form a gate electrode 110g and a gate insulating film 109g and to form an electrode 110p for protective diode. On this occasion, an upper layer part of the protective film 111 may be etched by overetching. The insulating film 113 below the gate electrode 110g may be regarded as a part of the gate insulating film.

As illustrated in FIG. 18J, a protective film 116 is formed on an entire surface. As illustrated in FIG. 18K, an opening exposing the gate electrode 110g and an opening exposing an the electrode 110p for protective diode are formed in the protective film 116. Then, a wiring 117 coupling the gate electrode 110g and the electrode 110p for protective diode to each other via those openings is formed. Note that it is preferable that at a time of forming the opening exposing the gate electrode 110g and the opening exposing the electrode 110p for protective diode, an opening exposing the source electrode 115s and an opening exposing the drain electrode 115d are also formed, and that at a time of forming the wiring 117, a wiring for a source and a wiring for a drain are also formed.

As illustrated in FIG. 18L, in a state that the gate electrode 110g, the source electrode 115s, and the drain electrode 115d are short-circuited, a voltage equal to or more than a breakdown voltage of the insulating film 109, for example, +25 V, is applied to the electrode 110p for protective diode from the outside. As a result, the insulating film 109 below the electrode 110p for protective diode is made broken down. On this occasion, the insulating film 113 below the electrode 110p for protective diode is not broken down, and functions as an insulating film of the MIS diode.

In the ninth embodiment also, even if a voltage exceeding a breakdown voltage of the gate insulating film 109g is applied to the gate electrode 110g as a surge voltage out of design, a leak current flows to the MIS diode before the gate insulating film 109g is broken down. In other words, it is possible to protect the gate insulating film 109g from breakdown.

### Tenth Embodiment

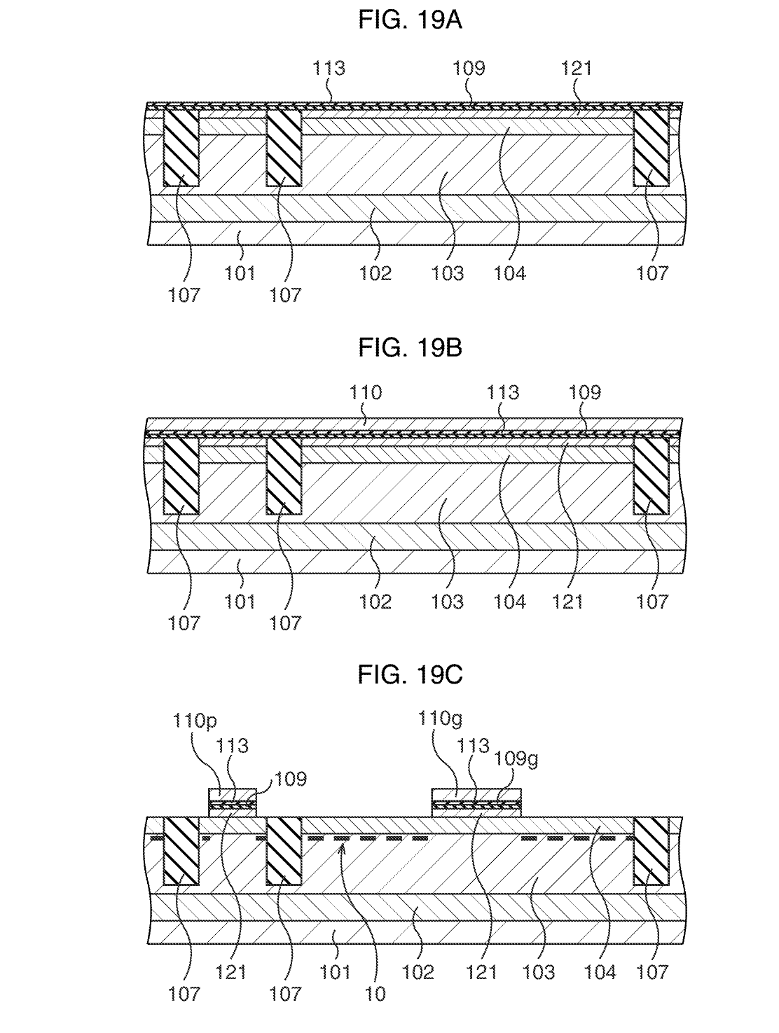

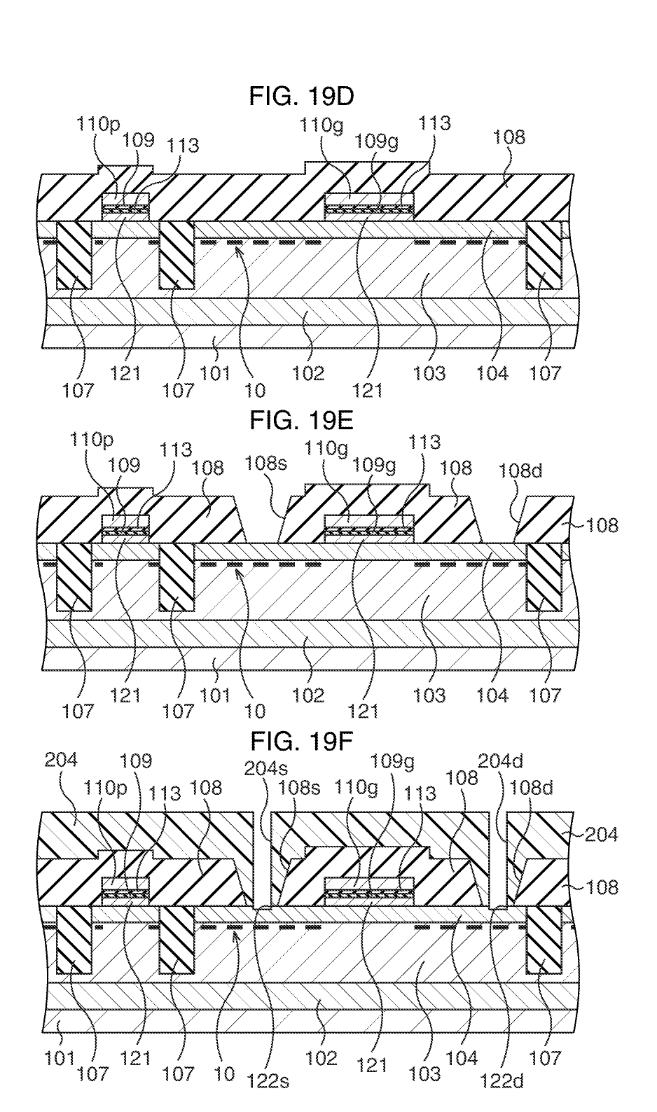

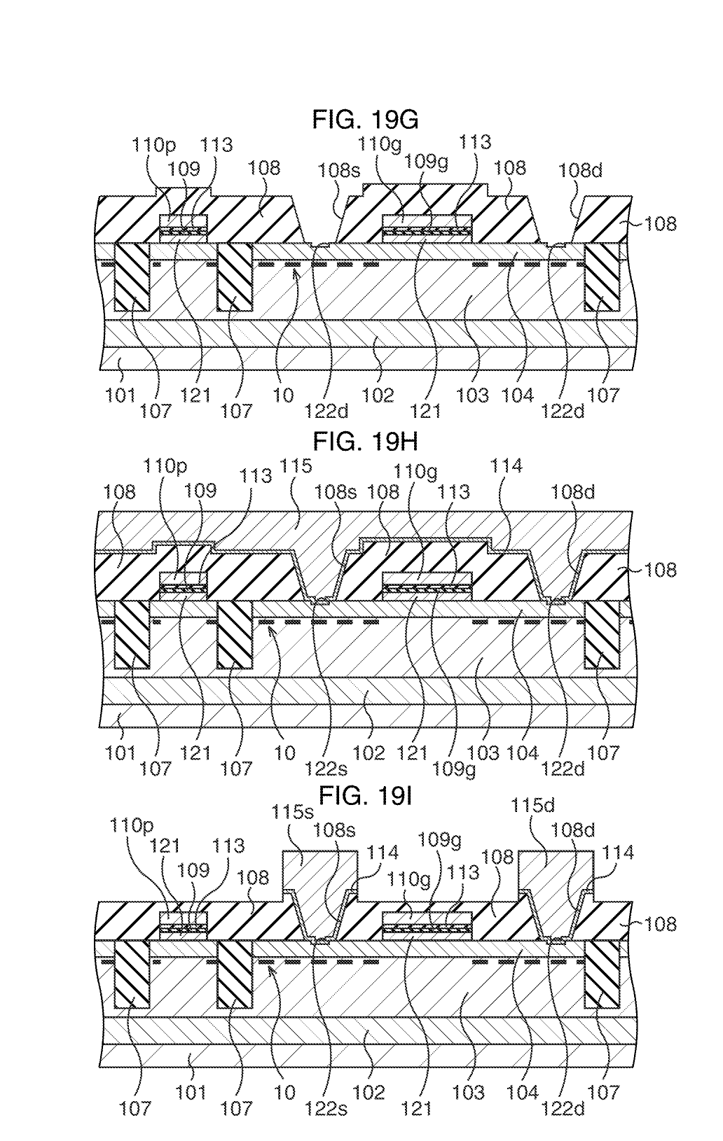

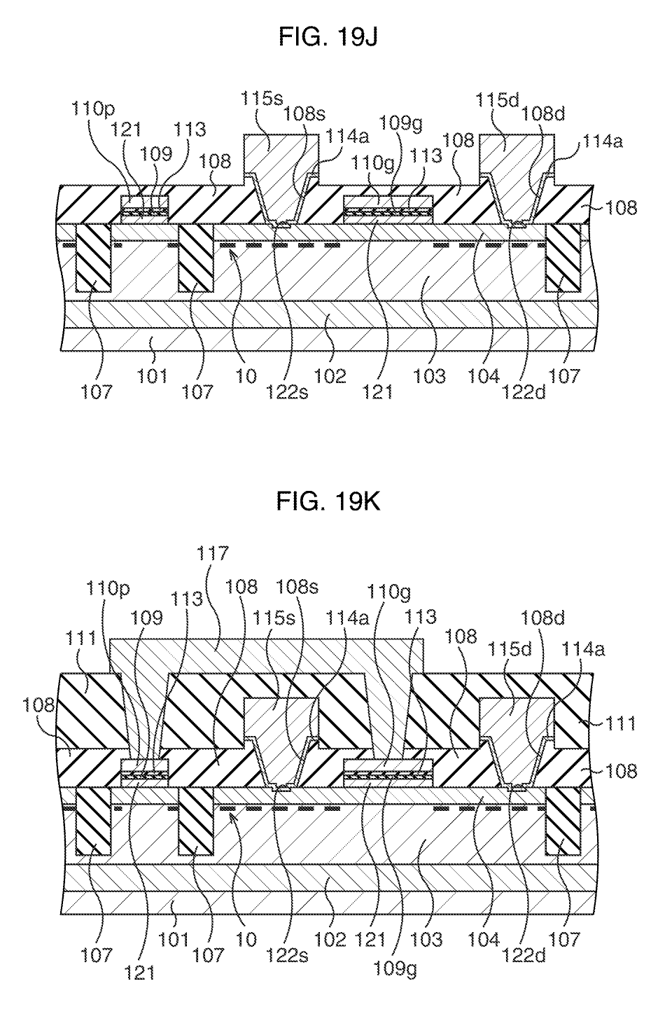

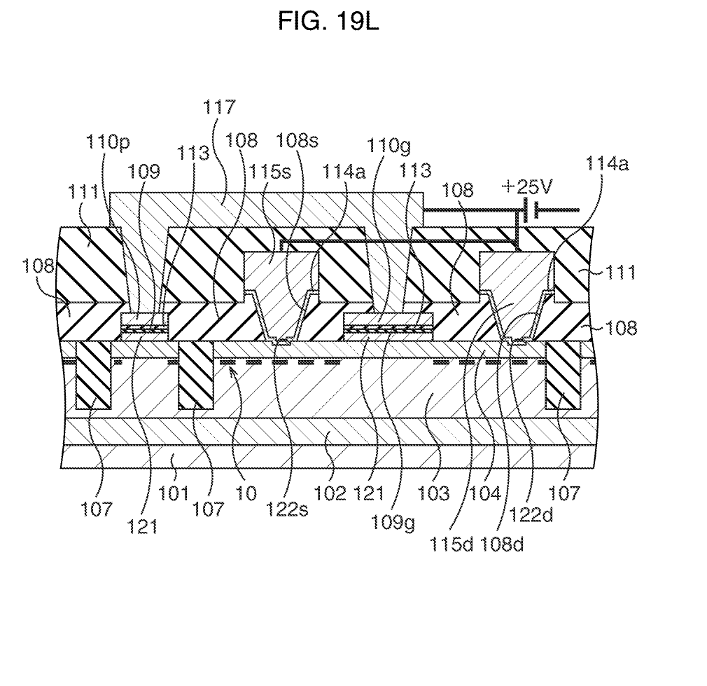

Next, a tenth embodiment will be described. Also in here, for the sake of convenience, a cross-sectional structure of a semiconductor device is described together with a method for manufacturing the same. Note that explanation of configurations similar to those of the second embodiment and the sixth embodiment, such as a material and a film thickness, is partly omitted. FIG. 19A to FIG. 19L are cross-sectional views depicting a method for manufacturing a semiconductor device according to the tenth embodiment in order of process steps. In the tenth embodiment, a 2DEG suppressing layer reducing a two-dimensional electron gas (2DEG) is formed before a gate electrode of a HEMT is formed. Further, an electrode of a MIS diode is formed concurrently with a gate electrode of the HEMT, and thereafter, a source electrode and a drain electrode of the HEMT are formed. Further, an insulating film the same as a gate insulating film is placed also between the electrode of the MIS diode and a nitride semiconductor layer, and the insulating film is made broken down.

First, processings to formation of an insulating film 109 are performed similarly to the sixth embodiment (see FIG. 14C). As illustrated in FIG. 19A, an insulating film 113 of a protective diode (MIS diode) is formed on the insulating film 109. It is preferable to perform an annealing treatment (PDA: post deposition anneal) between formation of the insulating film 109 and formation of the insulating film 113. As illustrated in FIG. 19B, a conductive film 110 to be the gate electrode is formed on the insulating film 113. As illustrated in FIG. 19C, the conductive film 110, the insulating film 113, the insulating film 109, and a 2DEG suppressing layer 121 are patterned thereby to form a gate electrode 110g and a gate insulating film 109g and to form an electrode 110p for protective diode. The insulating film 113 below the gate electrode 110g may be regarded as a part of the gate insulating film.

As illustrated in FIG. 19D, a protective film 108 is formed on an entire surface. As illustrated in FIG. 19E, an opening 108s and an opening 108d are each formed in respective regions in which the source electrode and the drain electrode are to be formed, of the protective film 108. As illustrated in FIG. 19F, a resist pattern 204 having openings 204s and 204d respectively in regions in which respective recesses for a source and a drain of the HEMT are to be formed is formed on the protective film 108. Subsequently, using the resist pattern 204 as a mask, an electron supply layer 104 is etched thereby to form a recess 122s for the source and recess 122d for the drain.

Then, as illustrated in FIG. 19G, the resist pattern 204 is removed. Note that processings from formation to removal of the resist pattern 204 including formation of the recesses 122s and 122d may be omitted. As illustrated in FIG. 19H, a conductive film 114 and a conductive film 115 to be the source electrode and the drain electrode are formed on an entire surface. As illustrated in FIG. 19I, the conductive film 115 and the conductive film 114 are patterned thereby to form a source electrode 115s and a drain electrode 115d. On this occasion, an upper layer part of the protective film 108 is also etched by overetching, so that an exposed upper surface of the protective film 108 is planarized.

As illustrated in FIG. 19J, an annealing treatment is performed thereby to change the conductive film 114 to a conductive film 114a with a lower contact resistance. As illustrated in FIG. 19K, a protective film 111 is formed on an entire surface. Subsequently, an opening exposing the gate electrode 110g and an opening exposing the electrode 110p for protective diode are formed in the protective film 111 and the protective film 108. Then, a wiring 117 coupling the gate electrode 110g and the electrode 110p for protective diode to each other via those openings is formed. Note that it is preferable that at a time of forming the opening exposing the gate electrode 110g and the opening exposing the electrode 110p for protective diode, an opening exposing the source electrode 115s and an opening exposing the drain electrode 115d are also formed, and that at a time of forming the wiring 117, a wiring for the source and a wiring for the drain are also formed.

As illustrated in FIG. 19L, in a state that the gate electrode 110g, the source electrode 115s, and the drain electrode 115d are short-circuited, a voltage equal to or more than a breakdown voltage of the insulating film 109, for example, +25 V, is applied to the electrode 110p for protective diode from the outside. As a result, the insulating film 109 below the electrode 110p for protective diode is made broken down. On this occasion, the insulating film 113 below the electrode 110p for protective diode is not broken down, and functions as an insulating film of the MIS diode.

In the tenth embodiment also, even if a voltage exceeding a breakdown voltage of the gate insulating film 109g is applied to the gate electrode 110g as a surge voltage out of design, a leak current flows to the MIS diode before the gate insulating film 109g is broken down. In other words, it is possible to protect the gate insulating film 109g from breakdown. Further, since a 2DEG 10 does not exist below the gate electrode 110g, a normally-off operation can be realized.

Incidentally, a material of a nitride semiconductor layer, for example, an electron transit layer and an electron supply layer of a HEMT, is not limited to a GaN-based semiconductor, but an AlN-based semiconductor may be used. For example, it is permissible that an InAlN layer is used as an electron transit layer while an AlN layer is used as an electron supply layer.

According to the above-described semiconductor device and the like, since the protective diode having the proper insulating film is formed on the substrate the same as that of the transistor including the nitride semiconductor layer, the transistor can be properly protected by a simple structure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device, comprising:
a substrate;
a transistor having a first nitride semiconductor layer above the substrate, a gate insulating film on the first nitride semiconductor layer, and a gate electrode on the gate insulating film; and
a protective diode having a second nitride semiconductor layer above the substrate, the second nitride semiconductor layer being isolated from the first nitride semiconductor layer, an insulating film on the second nitride semiconductor layer, and an electrode on the insulating film, wherein
the gate electrode and the electrode are coupled to each other,
the insulating film makes a leak current flow between the electrode and the second nitride semiconductor layer when a voltage equal to or more than a given value is applied to the gate electrode, and
the given value is higher than a voltage by which the transistor is on-operated and is lower than a breakdown voltage of the gate insulating film.

2. The semiconductor device according to claim 1, wherein a material of the insulating film is different from a material of the gate insulating film.

3. The semiconductor device according to claim 1, wherein a potential barrier width of the insulating film against the second nitride semiconductor layer and the electrode is smaller than a potential barrier width of the gate insulating film against the first nitride semiconductor layer and the gate electrode.

4. The semiconductor device according to claim 1, wherein the gate insulating film is an aluminum oxide film.

5. The semiconductor device according to claim 1, wherein the insulating film is a silicon nitride film or an aluminum nitride film.

6. The semiconductor device according to claim 5, wherein a thickness of the silicon nitride film is equal to or more than 10 nm and equal to or less than 62 nm.

7. The semiconductor device according to claim 5, wherein a thickness of the aluminum nitride film is equal to or more than 15 nm and equal to or less than 78 nm.

8. The semiconductor device according to claim 1, wherein a barrier height of the electrode against the second nitride semiconductor layer is lower than a barrier height of the gate electrode against the first nitride semiconductor layer.

9. The semiconductor device according to claim 1, wherein a dielectric constant of the insulating film is smaller than a dielectric constant of the gate insulting film.

10. A method for manufacturing a semiconductor device, comprising:
forming a first nitride semiconductor layer and a second nitride semiconductor layer isolated from each other above a substrate;
forming a transistor having a gate insulating film on the first nitride semiconductor layer and a gate electrode on the gate insulating film;
forming a protective diode having an insulating film on the second nitride semiconductor layer and an electrode on the insulating film; and
coupling the gate electrode and the electrode to each other, wherein
the insulating film makes a leak current flow between the electrode and the second nitride semiconductor layer when a voltage equal to or more than a given value is applied to the gate electrode, and
the given value is higher than a voltage by which the transistor is on-operated and lower than a breakdown voltage of the gate insulating film.

11. The method for manufacturing a semiconductor device according to claim 10, wherein a material of the insulating film is different from a material of the gate insulating film.

12. The method for manufacturing a semiconductor device according to claim 10, wherein a potential barrier width of the insulating film against the second nitride semiconductor layer and the electrode is smaller than a potential barrier width of the gate insulating film against the first nitride semiconductor layer and the gate electrode.

13. The method for manufacturing a semiconductor device according to claim 10, wherein the gate insulating film is an aluminum oxide film.

14. The method for manufacturing a semiconductor device according to claim 10, wherein the insulating film is a silicon nitride film or an aluminum nitride film.

15. The method for manufacturing a semiconductor device according to claim 10, wherein the electrode is formed after formation of the gate electrode, concurrently with a source electrode and a drain electrode of the transistor.

16. The method for manufacturing a semiconductor device according to claim 10, wherein the electrode is formed concurrently with the gate electrode, and thereafter, a source electrode and a drain electrode of the transistor are formed.

17. The method for manufacturing a semiconductor device according to claim 10, wherein the electrode is formed before formation of the gate electrode, concurrently with a source electrode and a drain electrode of the transistor.

18. The method for manufacturing a semiconductor device according to claim 10, wherein, after a source electrode and a drain electrode of the transistor are formed, the electrode is formed concurrently with the gate electrode.

19. The method for manufacturing a semiconductor device according to claim 10, comprising, before the forming the gate electrode, forming a two-dimensional electron gas suppressing layer reducing a two-dimensional electron gas below the gate electrode in the first nitride semiconductor layer.

20. A semiconductor device, comprising:
a gallium nitride based compound semiconductor substrate,
a transistor having a first insulating film on the gallium nitride based compound semiconductor substrate and a gate electrode on the first insulating film, and
an element having a second insulating film on the gallium nitride based compound semiconductor substrate and different from the first insulating film in materials, and a conductive film on the second insulating film, the conductive film being coupled to the gate electrode.
